(19) United States
(12) Patent Application Publication
(10) Pub. No.: US 2007/0001269 A1
(43) Pub. Date: Jan. 4, 2007

(54) Nitride semiconductor device

(75) Inventors: Takashi Kano, Hirakata-City (JP); Kiyoshi Oota, Neyagawa-City (JP)

Correspondence Address: NDQ&M WATCHSTONE LLP, 1300 EYE STREET, NW, 400 EAST TOWER, WASHINGTON, DC, 20005, US

(73) Assignee: Sanyo Electric Co., Ltd., Moriguchi-City (JP)

(21) Appl. No.: 11/475,955

(22) Filed: Jun. 28, 2006

(30) Foreign Application Priority Data
Jun. 29, 2005 (JP) 2005-190316
Jun. 8, 2006 (JP) 2006-160157

(51) Int. Cl. H01L 23/58

(52) U.S. Cl. 257/640

(57) ABSTRACT

A nitride semiconductor device includes a nitride semiconductor layer having a main surface, and an ohmic electrode formed on the main surface of the nitride semiconductor layer The ohmic electrode includes a silicon layer formed to contact with the main surface of the nitride semiconductor layer, and a first metal layer formed on the silicon layer.

### CROSS REFERENCE TO RELATED APPLICATIONS

This application is based upon and claims the benefit of priority from prior Japanese Patent Application No. 2005-190316, filed on June 29 and Japanese Patent Application No. 2006-160157, filed on June 8; the entire contents of which are incorporated herein by reference.

### BACKGROUND OF THE INVENTION

1. Field of the Invention

The present invention relates to a nitride semiconductor device, and particularly to a nitride semiconductor device which is provided with an ohmic electrode formed on a nitride semiconductor layer.

2. Description of the Prior Art

Conventionally, a nitride semiconductor device, which is provided with an ohmic electrode Armed on a nitride semiconductor layer, has been known (for example, refer to Unexamined Japanese Patent Application No. Hei 9 (1995)-69623.

In the above-mentioned Japanese Patent Application, disclosed is a technology where the ohmic electrode is annealed at a temperature of about 500° C. to about 700° C. after forming the ohmic electrode is formed on an n-type nitride semiconductor layer. The technology also discloses the ohmic electrode has a favorable ohmic contact with a nitride semiconductor layer.

The nitride semiconductor device has been conventionally known, that has an ohmic electrode, and that is provided with a layer essentially containing Al, a Ti layer, and the like are formed to contact with main surfaces of nitride semiconductor layers such as an InGaN layer, an AlGaN layer, and the like. According to this nitride semiconductor device, in a state of having been manufactured by a wafer process, ohmic characteristics between the ohmic electrode and a nitride semiconductor layer are favorable. However, when the heat of about 250° C. to about 350° C. is applied thereto during soldering and the like in an assembling process, the ohmic characteristics are deteriorated. When, as described above, the ohmic characteristics between the ohmic electrode and the nitride semiconductor layer are deteriorated, a forward voltage (Vf) of a diode characteristic is increased, and hence, a disadvantage such as increase of power consumption arises. For this reason, conventionally, as in the case of Japanese Patent Application described above, the ohmic electrode is annealed at a high temperature of about 500° C. to about 700° C. after forming the ohmic electrode, and the ohmic electrode is caused to have a favorable ohmic contact with the nitride semiconductor layer.

### SUMMARY OF THE INVENTION

The inventers of the present application has discovered that deterioration of the ohmic characteristics between an ohmic electrode and a nitride semiconductor layer cased by heat, can be suppressed by configuring the ohmic electrode formed on the nitride semiconductor layer to include a silicon layer.

That is, a nitride semiconductor device of a first aspect of the present invention includes a nitride semiconductor layer having a main surface, and an ohmic electrode formed on the main surface of the nitride semiconductor layer. The ohmic electrode includes a silicon layer formed to contact with the main surface of the nitride semiconductor layer, and a first metal layer formed on the silicon layer.

According to this nitride semiconductor device of the first aspect, as described above, the ohmic electrode is configured to include a silicon layer formed to contact with a main surface of the nitride semiconductor layer, and the first metal formed on the silicon layer. Thus, due to an effect of the silicon layer contacts with the main surface of the nitride semiconductor layer, even when the heat of, for example, about 250° C. to about 360° C. is a applied in the assembling of the ohmic electrode after forming of the ohmic electrode, deterioration of ohmic characteristics can be suppressed. That is, the deterioration, due to heat, of the ohmic characteristics between the ohmic electrode and the nitride semiconductor layer, can be suppressed. This point has been validated by an experiment to be described later. The following points can be considered as the effects of the silicon layer. Unlike the case where the first metal layer is formed directly on a main surface of the nitride semiconductor layer having a large band-gap (e.g., band-gap thereof is about 3.5 eV), the first metal layer is formed with an interposed silicon layer having a small band-gap (e.g., band-gap thereof is about 1.1 eV). Thereby, it is possible to cause the ohmic electrode to form a more favorable ohmic contact with the nitride semiconductor layer, and to maintain the above favorable ohmic contact even when the heat of about 250° C. to about 350° C. is applied at the time of assembly.

In the nitride semiconductor device of the first aspect, it is preferable that the first metal layer includes a metal forming an ohmic contact with the nitride semiconductor layer.

In the nitride semiconductor device of the first aspect, it is preferable that the ohmic electrode is formed on a p-type nitride semiconductor layer, and the first metal layer includes at least one of a Pd and a Pt. When a nitride semiconductor device is configured as described above, even for a p-type nitride semiconductor layer having a difficulty in forming an ohmic contact, it is possible to easily form a more favorable ohmic contact between the ohmic electrode and the p-type nitride semiconductor layer. In addition, a state of the above favorable ohmic contact can be maintained even when the heat of about 250° C. to about 350° C. is applied at the time of assembly. This is achieved by forming the first metal layer, which includes at least one of Pd and Pt, on the p-type nitride semiconductor layer with a silicon layer interposed in between.

In the nitride semiconductor device of the first aspect, it is preferable that the ohmic electrode is formed on the n-type nitride semiconductor layer, and further includes an Al layer disposed between the silicon layer and the first metal layer. When a nitride semiconductor device is configured as described above, in the case where the ohmic electrode is formed on the n-type nitride semiconductor layer, it is possible to easily form a more favorable ohmic contact between the ohmic electrode and the n-type nitride semiconductor layer, and to maintain the above favorable ohmic contact even when the heat of about 250° C. to about 350° C. is applied at the time of assembly.

In the nitride semiconductor device of the first aspect, it is preferable that the ohmic electrode is formed on the n-type nitride semiconductor layer, and the ohmic electrode includes at least one of a Pd layer and a Pt layer between the silicon layer and the first metal layer.

In the nitride semiconductor device of the first aspect, it is preferable that the silicon layer is configured of amorphous silicon. When a nitride semiconductor device is configured as described above, since amorphous silicon contains a large number of defects, a conductive state is produced between the nitride semiconductor layer and the ohmic electrode due to the presence of the defects contained in the amorphous silicon. Thus, it is considered that deterioration of the ohmic characteristics of the ohmic electrode can be suppressed, the deterioration being caused by heat produced in the assembling of a nitride semiconductor electric device having the nitride semiconductor device.

In the nitride semiconductor device of the first aspect, it is preferable that the nitride semiconductor device is further provided with a second metal layer formed on the ohmic electrode. When a nitride semiconductor device is configured as described above, the ohmic electrode can be easily electrically contacted with an exterior through a second metal layer.

In the nitride semiconductor device of the first aspect, it is preferable that the silicon layer has a thickness equal to or more than 0.5 nm and equal to or less than 30 nm. It has been validated by an experiment that, when the silicon layer has a thickness such as above, it is possible to easily form a more favorable ohmic contact between the ohmic electrode and the nitride semiconductor layer, and to maintain the above favorable ohmic contact even when the heat of about 250° C. to about 350° C. is applied at the time of assembly.

A nitride semiconductor device of a second aspect of the present invention is provided with a p-type nitride semiconductor layer, and an ohmic electrode formed on the p-type nitride semiconductor layer The ohmic electrode includes a silicon layer formed on the p-type nitride semiconductor layer, and a first metal layer formed on the silicon layer.

According to the nitride semiconductor device of the -second aspect, as described above, the ohmic electrode is configured to include the silicon layer formed on the p-type nitride semiconductor layer, and the first metal layer formed on the silicon layer. Thus, due to an effect of the silicon layer formed on the p-type nitride semiconductor layer, even for the p-type nitride semiconductor layer, which has a difficulty in forming an ohmic contact, a favorable ohmic contact can be obtained between the ohmic electrode and the p-type nitride semiconductor layer; and even when the heat of, for example, about 250° C. to about 350° C. is applied in the assembling of the ohmic electrode after the forming of the ohmic electrode, deterioration of ohmic characteristics can be suppressed That is, deterioration, due to heat, of the ohmic characteristics between the ohmic electrode and the p-type nitride semiconductor layer can be suppressed. This point has been validated by an experiment to be described later. The following points can be considered as the effects of the silicon layer. Unlike the case where the first metal layer is formed directly on a main surface of the nitride semiconductor layer having a large band-gap (e.g., band-gap thereof is about 3.5 eV), the first metal layer is formed with an interposed silicon layer having a small band-gap (e.g., band-gap thereof is about 1.1 eV). Thereby, it is possible to cause the ohmic electrode to form a more favorable ohmic contact with the p-type nitride semiconductor layer, and to maintain the above favorable ohmic contact even when the heat of about 250° C. to about 350° C. is applied at the time of assembly.

In the nitride semiconductor device of the second aspect, it is preferable that an ohmic metal layer is provided between the p-type nitride semiconductor layer and the silicon layer. The ohmic metal layer forms an ohmic contact with the p-type nitride semiconductor layer. As described above, due to an effect of the silicon layer, even when the silicon layer is formed on the p-type nitride semiconductor layer through the ohmic metal layer, and when the first metal layer is formed on the silicon layer, it is possible to form more favorable ohmic contact between the p-type nitride semiconductor layer and the ohmic electrode including the ohmic metal layer, the silicon layer, and the first metal layer. In addition, the above favorable ohmic contact can be maintained even when the heat of about 250° C. to about 350° C. is applied at the time of assembly.

A nitride semiconductor device of a third aspect of the present invention is provided with an n-type nitride semiconductor layer, and an ohmic electrode formed on the n-type nitride semiconductor layer. The ohmic electrode includes a silicon layer formed on the n-type nitride semiconductor layer, and a first metal layer formed on the silicon layer. The first metal layer includes a material forming an ohmic contact with the n-type nitride semiconductor layer, and the ohmic electrode includes at least one of a Pd layer and a Pt layer between the silicon layer and the first metal layer.

In the nitride semiconductor device of the third aspect, the silicon layer and the Pd layer, or the silicon layer and the Pt layer, are formed between the n-type nitride semiconductor device and the first metal For this reason, deterioration of the characteristics of the ohmic electrode can be suppressed, the deterioration caused by the influence of heat produced in the assembling of a nitride semiconductor electric device having a nitride semiconductor device.

Here, Pd layer and Pt layer are materials forming ohmic contact with the p-type nitride semiconductor layer, while forming schottky junction with the n-type nitride semiconductor layer. In the nitride semiconductor of the present aspect, to suppress the deterioration in characteristics of the ohmic electrode, Pd layer of Pt layer which does not generally used as the ohmic electrode of the n-type nitride semiconductor layer, is included in the ohmic electrode.

In the nitride semiconductor device of the third aspect, it is preferable that the silicon layer is configured of amorphous silicon. When a nitride semiconductor device is configured as described above, since amorphous silicon contains a large number of defects, a conductive state is produced between the n-type nitride semiconductor layer and the Pd layer (or the Pt layer) due to the presence of the defects contained in the amorphous silicon. It is, therefore, considered that, even when the heat of 300° C. to 400° C. is applied in the assembling of a nitride semiconductor electric device having a nitride semiconductor device, an ohmic contact between the n-type nitride semiconductor device and the first metal layer is maintained except that a small amount of reaction occurs between the first metal and the Pd layer (or, the Pt layer).

### BRIEF DESCRIPTION OF THE DRAWINGS

FIG. 1 is a sectional view showing a structure of a nitride semiconductor laser device (a nitride semiconductor device) of a first embodiment of the present invention.

FIG. 2 is a view for describing in detail the structure of the nitride semiconductor laser device of the first embodiment shown in FIG. 1.

FIG. 3 is a view for describing in detail the structure of the nitride semiconductor laser device of the first embodiment shown in FIG. 1.

FIG. 4 is a view for describing in detail the structure of the nitride semiconductor laser device of the first embodiment shown in FIG. 1

FIG. 5 is a sectional view for describing in detail a process of manufacturing the nitride semiconductor laser device of the first embodiment shown in FIG. 1.

FIG. 6 is a sectional view for describing in detail the process of manufacturing the nitride semiconductor laser device of the first embodiment shown in FIG. 1.

FIG. 7 is a sectional view for describing in detail the process of manufacturing the nitride semiconductor laser device of the first embodiment shown in FIG. 1.

FIG. 8 is a sectional view for describing in detail the process of manufacturing the nitride semiconductor laser device of the first embodiment shown in FIG. 1.

FIG. 9 is a view for describing an experiment which is conducted for validating an effect of a nitride semiconductor laser device of the first embodiment shown in FIG. 1.

FIG. 10 is a view for describing the experiment which is conducted for validating the effect of the nitride semiconductor laser device of the first embodiment shown in FIG. 1.

FIG. 11 is a view for describing the experiment which is conducted for validating the effect of the nitride semiconductor laser device of the first embodiment shown in FIG. 1

FIG. 12 is a view for describing the experiment which is conducted for validating the effect of the nitride semiconductor laser device of the first embodiment shown in FIG. 1

FIG. 13 is a view for describing the experiment which is conducted for validating the effect of the nitride semiconductor laser device of the first embodiment shown in FIG. 1.

FIG. 14 is a view for describing the experiment which is conducted for validating the effect of the nitride semiconductor laser device of the first embodiment shown in FIG. 1.

FIG. 15 is a view for describing the experiment which is conducted for validating the effect of the nitride semiconductor laser device of the first embodiment shown in FIG. 1.

FIG. 16 is a view for describing the experiment which is conducted for validating the effect of the nitride semiconductor laser device of the first embodiment shown in FIG. 1.

FIG. 17 is a view for describing the experiment which is conducted for validating the effect of the nitride semiconductor laser device of the first embodiment shown in FIG. 1.

FIG. 18 is a view for describing the experiment which is conducted for validating the effect of the nitride semiconductor laser device of the first embodiment shown in FIG. 1.

FIG. 20 is a view for describing the experiment which is conducted for validating the effect of the nitride semiconductor laser device of the first embodiment shown in FIG. 1.

FIG. 21 is a view for describing the experiment which is conducted for validating the effect of the nitride semiconductor laser device of the first embodiment shown in FIG. 1.

FIG. 22 is a view for describing the experiment which is conducted for validating the effect of the nitride semiconductor laser device of the first embodiment shown in FIG. 1.

FIG. 23 is a view for describing the experiment which is conducted for validating the effect of the nitride semiconductor laser device of the first embodiment shown in FIG. 1.

FIG. 24 is a view for describing the experiment which is conducted for validating the effect of the nitride semiconductor laser device of the first embodiment shown in FIG. 1.

FIG. 25 is a sectional view showing a structure of a nitride semiconductor laser device (a nitride semiconductor device) of a second embodiment of the present invention.

FIG. 26 is a view for describing in detail the structure of the nitride semiconductor laser device of the second embodiment shown in FIG. 25.

FIG. 27 is a sectional view for describing a process of manufacturing the nitride semiconductor laser device of the second embodiment shown in FIG. 25.

FIG. 28 is a sectional view for describing the process of manufacturing the nitride semiconductor laser device of the second embodiment shown in FIG. 25.

FIG. 29 is a sectional view for describing the process of manufacturing the nitride semiconductor laser device of the second embodiment shown in FIG. 25.

FIG. 30 is a sectional view for describing the process of manufacturing the nitride semiconductor laser device of the second embodiment shown in FIG. 25.

FIG. 31 is a sectional view showing a structure of a nitride semiconductor light-emitting diode device (a nitride semiconductor device) of a third embodiment of the present invention.

FIG. 32 is a view for describing in detail the structure of the nitride semiconductor light-emitting diode device of the third embodiment shown in FIG. 31.

FIG. 33 is a view for describing in detail the structure of the nitride semiconductor light-emitting diode device of the third embodiment shown in FIG. 31.

FIG. 34 is a sectional view for describing a process of manufacturing the nitride semiconductor light-emitting diode device of the third embodiment shown in FIG. 31.

FIG. 35 is a sectional view for describing the process of manufacturing the nitride semiconductor light-emitting diode device of the third embodiment shown in FIG. 31.

FIG. 36 is a sectional view for describing the process of manufacturing the nitride semiconductor light-emitting diode device of the third embodiment shown in FIG. 31.

FIG. 37 is a sectional view for describing the process of manufacturing X the nitride semiconductor light-emitting diode device of the third embodiment shown in FIG. 31.

FIG. 38 is a sectional view for describing the process of manufacturing the nitride semiconductor light-emitting diode device of the third embodiment shown in FIG. 31.

FIG. 39 is a view for describing an experiment which is conducted for validating an effect of a p-side ohmic electrode of the nitride semiconductor light-emitting diode device of the third embodiment shown in FIG. 31.

FIG. 40 is a sectional view showing a structure of a nitride semiconductor light-emitting diode device (a nitride semiconductor device) of a fourth embodiment of the present invention.

FIG. 41 is a view for describing in detail the structure of the nitride semiconductor light-emitting diode device of the fourth embodiment shown in FIG. 40.

FIG. 42 is a view for describing in detail the structure of the nitride semiconductor light-emitting diode device of the fourth embodiment shown in FIG. 40.

FIG. 43 is a sectional view for describing a process of manufacturing the nitride semiconductor light-emitting diode device of the fourth embodiment shown in FIG. 40.

FIG. 44 is a sectional view for describing the process of manufacturing the nitride semiconductor light-emitting diode device of the fourth embodiment shown in FIG. 40.

FIG. 45 is a sectional view for describing the process of manufacturing the nitride semiconductor light-emitting diode device of the fourth embodiment shown in FIG. 40.

FIG. 46 is a sectional view for describing the process of manufacturing the nitride semiconductor light-emitting diode device of the fourth embodiment shown in FIG. 40.

FIG. 47 is a view for describing an experiment which is conducted for validating an effect of a p-side ohmic electrode of the nitride semiconductor light-emitting diode device of the fourth embodiment shown in FIG. 40.

FIG. 48 is a view for describing the experiment which is conducted for validating an effect of a p-side ohmic electrode of the nitride semiconductor light-emitting diode device of the fourth embodiment shown in FIG. 40.

FIG. 49 is a sectional view showing a structure of a nitride semiconductor laser device (a nitride semiconductor device) of a fifth embodiment of the present invention.

FIG. 50 is a view for describing in detail the structure of the nitride semiconductor laser device of the fifth embodiment shown in FIG. 49.

FIG. 51 is a view for describing in detail the structure of the nitride semiconductor laser device of the fifth embodiment shown in FIG. 49.

FIG. 52 is a view for describing an experiment which is conducted for validating an effect of a p-side ohmic electrode of the nitride semiconductor laser device of the fifth embodiment shown in FIG. 49.

FIG. 53 is a view for describing the experiment which is conducted for validating an effect of a p-side ohmic electrode of the nitride semiconductor laser device of the fifth embodiment shown in FIG. 49.

FIG. 54 is a sectional view showing a structure of a nitride semiconductor laser device (a nitride semiconductor device) of a sixth embodiment of the present invention.

FIG. 55 is a view for describing in detail the structure of the nitride semiconductor laser device of the sixth embodiment shown in FIG. 54.

FIG. 56 is a view for describing in detail the structure of the nitride semiconductor laser device of the sixth embodiment shown in FIG. 54.

FIG. 57 is a sectional view showing a structure of a bipolar transistor (a nitride semiconductor device) of a seventh embodiment of the present invention.

FIG. 58 is a view for describing in detail the structure of the bipolar transistor of the seventh embodiment shown in FIG. 57.

FIG. 59 is a view for describing in detail the structure of the bipolar transistor of the seventh embodiment shown in FIG. 57.

FIG. 60 is a view for describing in detail the structure of the bipolar transistor of the seventh embodiment shown in FIG. 57.

FIG. 61 is a sectional view for describing a process of manufacturing the bipolar transistor of the seventh embodiment shown in FIG. 57.

FIG. 62 is a sectional view for describing the process of manufacturing the bipolar transistor of the seventh embodiment shown in FIG. 57.

FIG. 63 is a sectional view for describing the process of manufacturing the bipolar transistor of the seventh embodiment shown in FIG. 57.

FIG. 64 is a sectional view for describing the process of manufacturing the bipolar transistor of the seventh embodiment shown in FIG. 57.

FIG. 65 is a sectional view showing a structure of a nitride semiconductor device of an eighth embodiment of the present invention.

FIG. 66 is a view for describing in detail the structure of the nitride semiconductor device of the eighth embodiment shown in FIG. 65.

FIG. 67 is a view for describing in detail the structure of the nitride semiconductor device of the eighth embodiment shown in FIG. 65.

FIG. 68 is a sectional view showing a structure of a nitride semiconductor device of a ninth embodiment of the present invention.

FIG. 69 is a view for describing in detail the structure of the nitride semiconductor device of the ninth embodiment shown in FIG. 68.

FIG. 70 is a view for describing in detail the structure of the nitride semiconductor device of the ninth embodiment shown in FIG. 68.

FIG. 71 is a view for describing an experiment which is conducted for validating an effect of an n-side ohmic electrode of the nitride semiconductor device of the eighth embodiment shown in FIG. 65, and an effect of the same of the ninth embodiment shown in FIG. 68.

FIG. 72 is a view for describing the experiment which is conducted for validating the effect of an n-side ohmic electrode of the nitride semiconductor device of the eighth embodiment shown in FIG. 65, and the effect of the same of the ninth embodiment shown in FIG. 68.

FIG. 73 is a view for describing the experiment which is conducted for validating the effect of an n-side ohmic electrode of the nitride semiconductor device of the eighth embodiment shown in FIG. 65, and the effect of the same of the ninth embodiment shown in FIG. 68.

FIG. 74 is a view for describing the experiment which is conducted for validating the effect of an n-side ohmic electrode of the nitride semiconductor device of the eighth embodiment shown in FIG. 65, and the effect of the same of the ninth embodiment shown in FIG. 68.

### DETAILED DESCRIPTION OF THE EMBODIMENTS

Hereinafter, embodiments of the present invention are described with reference to the accompanying drawings.

### First Embodiment

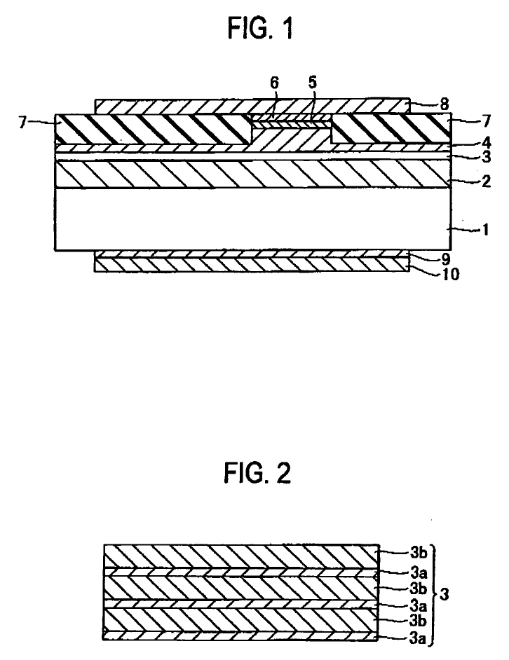

FIG. 1 is a sectional view showing a structure of a nitride semiconductor laser device (a nitride semiconductor device) of a first embodiment of the present invention. FIGS. 2 to 4 are views for describing in detail the structure of the nitride semiconductor laser device of the first embodiment shown in FIG. 1. First, referring to FIGS. 1 to 4, the structure of the nitride semiconductor laser device of the first embodiment is described.

In the nitride semiconductor laser device of the first embodiment, as shown in FIG. 1, an n-type clad layer 2, which is configured of AlₓGa₁₋ₓN (x=0.07) having a thickness of about 400 nm, is formed on a main surface of an n-type GaN substrate 1. Incidentally, the n-typo GaN substrate 1 is one example of an “n-type nitride semiconductor layer” of the present invention. On the n-type clad layer 2, an active layer 3 of an MQW structure (multi-quantum well structure) is formed. As shown in FIG. 2, this active layer 3 has the MQW structure, in which a plurality of well layers 3a and a plurality of barrier layers 3b are alternately stacked. Each of the well layers 3a is configured of InₓGa₁₋ₓN (x=0.15), and has a thickness of about 3 nm. Each of the barrier layers 3b is configured of InₓGa₁₋ₓN (x=0.02), and has a thickness of about 20 nm. On the active layer 3, as shown in FIG. 1, a p-type clad layer 4 configured of AlₓGa₁₋ₓN (x=0.07) doped with Mg is formed. The p-type dad layer 4 includes a convex portion of about 400 nm in thickness and a flat portion.

Moreover, on the convex portion of the p-type clad layer 4, a p-type contact layer 5 configured of InₓGa₁₋ₓN (x=0.02) doped with Mg, is formed. The p-type contact layer 5 has a thickness of about 10 nm. A ridge portion, which serves as a current passage, is formed with the convex portion of the p-type clad layer 4 and the p-type contact layer 5. Incidentally, the p-type contact layer 5 is one example of a “p-type nitride semiconductor layer” of the present invention. Furthermore, on the p-type contact layer 5, a p-side ohmic electrode 6 is formed. Incidentally, the p-side ohmic electrode 6 is one example of an “ohmic electrode” of the present invention.

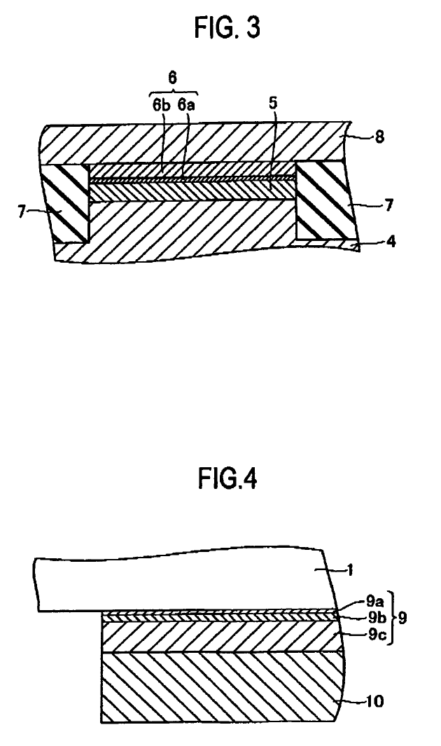

Here, in the first embodiment, as shown in FIG. 3, the p-side ohmic electrode 6 is configured of a Si (silicon) layer 6a, and a Pd layer 6b of about 20 nm in thickness. The Si layer 6a is configured of amorphous Ricon, has a thickness of about 1 nm, and is formed to contact with the p-type contact layer 5. Incidentally, the Pd layer 6b is one example of a “first metal layer” of the present invention.

In addition, as shown in FIG. 1, a current block layer 7 configured of SiO₂ is formed to cover a ridge portion and sides of the p-side ohmic electrode 6.

Moreover, in the first embodiment, a pad electrode 8 is formed on predetermined regions of the p-side ohmic electrode 6 and the current block layer 7 so that the pad electrode 8 contacts with an upper surface of the p-side ohmic electrode 6. Incidentally, the pad electrode 8 is one example of a “second metal layer” of the present invention. This pad electrode 8 is configured of a Ti layer (not shown) of about 100 nm in thickness, a Pd layer (not shown) of about 150 nm in thickness, and an Au layer (not shown) of about 300 nm in thickness. The Ti layer, the Pd layer and the Au layer are disposed in the above sequence from the side of the p-side ohmic electrode 6.

Furthermore, on a predetermined region of a reverse side (a lower surface) of the n-type GaN substrate 1, an n-type ohmic electrode 9 is formed. Incidentally, the n-type ohmic electrode 9 is one example of the “ohmic electrode” of the present invention.

In addition, in the first embodiment, as shown in FIG. 4, the n-type ohmic electrode 9 is configured of a Si layer 9a of 10 nm in thickness, an Al layer 9b of about 6 nm in thickness; and a Pd layer 9c of about 30 nm in thickness. The Si layer 9a is configured of amorphous silicon, and contacts with a lower surface of the n-type GaN substrate 1. The Si layer 9a, the Al layer 9b and the Pd layer 9c are disposed in the above sequence from the side of the n-type GaN substrate 1. Incidentally, the Al layer 9b and the Pd layer 9c are examples of the “first metal layer” of the present invention. In addition, in the first embodiment, as shown in FIG. 1, a pad electrode 10 configured of an Au layer of about 300 nm in thickness is formed on a lower surface of the n-type ohmic electrode 9. Incidentally, the pad electrode 10 is one example of the “second metal layer” of the present invention.

Next, a description will be given for results of measurement of forward voltages at a time when a forward current of about 20 mA flows in a nitride semiconductor laser device of the first embodiment. It should be noted that, as a comparative example, forward voltages are measured also for a conventional nitride semiconductor laser device, in which the p-side ohmic electrode is provided with a Pd layer only and not with a Si layer, and in which the n-side ohmic electrode is provided with Al and Pd layers only and not with a Si layer. As a result in the nitride semiconductor laser device of the first embodiment, a forward voltage is 4.4 V after a wafer process, and is 4.2 V after an assembling process. In contrast, in a conventional nitride semiconductor laser device, the forward voltage after wafer process is 4.4 V, which is the same level as that of the above first embodiment, and the forward voltage after the assembling process is 7.5 V. In other words, in the conventional nitride semiconductor laser device, the forward voltage after the assembling process is increased. On the other hand, in the nitride semiconductor laser device of the first embodiment, the forward voltage after the assembling process is improved. From these results, it is confirmed that deterioration of the ohmic characteristics between the p-ride ohmic electrode 6 and the p-type contact layer 5, and deterioration of the ohmic characteristics between the n-side ohmic electrode 9 and the n-type GaN substrate 1, can be suppressed, the deterioration being caused by the heat of about 250° C. to about 350° C. applied during soldering in the assembling of the p-side ohmic electrode 6 and the n-side ohmic electrode 9 after the forming of the same. The above is achieved by configuring the p-side ohmic electrode 6 to include the Si layer 6a of about 1 nm in thickness which contacts with the p-type contact layer 5, and by configuring the n-side ohmic electrode 9 to include the Si layer 9a of about 1 nm in thickness which contacts with the n-type GaN substrate 1.

As described above, in the first embodiment, the p-side ohmic electrode 6 is configured to include the Si layer 6a of about 1 nm in thickness which contacts with a main surface of the p-type contact layer 5, and the Pd layer 6b of about 20 nm in thickness formed on the Si layer 6a. The n-side ohmic electrode 9 is configured to include the Si layer 9a of about 1 nm in thickness which contacts with a lower surface of the n-type GaN substrate 1, the Al layer 9b of about 6 nm in thickness formed on a lower surface of the Si layer 9a, and the Pd layer 9c of about 30 nm in thickness formed on a lower surface of the Al layer 9b. In this way, because of the effects of the Si layers 6a and 9a, which respectively contact with the main surfaces of the p-type contact layer 5 and the n-type GaN substrate 1, ohmic characteristics are not easily deteriorated even when the heat of about 260° C. to about 350° C. is applied during the soldering in the assembling of the p-side ohmic electrode 6 and the n-side ohmic electrode 9 after the forming of the same. Thus, deterioration of the ohmic characteristics between the p-side ohmic electrode 6 and the p-type contact layer 5, and deterioration of the ohmic characteristics between the n-side ohmic electrode 9 and the n-type GaN substrate 1 can be suppressed, deterioration being caused by heat. This point has been validated by an experiment to be described later The following points can be considered as the effects of the Si layers 6a and 9a. Unlike the case where the Pd layer 6b and the Al layer 9b are directly formed respectively on the main surfaces of the p-type contact layer 5 and the n-type GaN substrate 1, which have large band-gaps (band-gap: about 3.5 eV), the Pd layer 6b and the Al layer 9b are formed with the Si layers 6a and 9b, which have small band-gaps (band-gap: about 1.1 eV), and which are respectively interposed between the Pd layer 6b and the p-type contact layer 5, and between the Al layer 9b and the n-type GaN substrate 1. In this way, it can be considered that the p-side ohmic electrode 6 and the n-side ohmic electrode 9 can be caused to form a more favorable ohmic contact with the p-type contact layer 5 and the n-type GaN substrate 1, respectively; and that the favorable ohmic contacts described above can be maintained even when the heat of about 250° C. to about 350° C. is applied during soldering at the time of assembly.

Furthermore, in the first embodiment, by forming the Si layers 6a and 9a of amorphous silicon, the Si layers 6a and 9a configured of amorphous silicon contain a large number of defects (not shown). Thus, electrons are allowed to pass through the large number of defects (not shown). Accordingly, electrons are allowed to easily pass through with the Si layers 6a and 9a, which are respectively interposed between the Pd layer 6b and the p-type contact layer 5, and between the Al layer 9b and the n-type GUN substrate 1. The p-side ohmic electrode 6 and the n-side ohmic electrode 9 are, therefore, allowed to easily form a ohmic contact with the p-type contact layer 5 and the n-type GaN substrate 1, respectively.

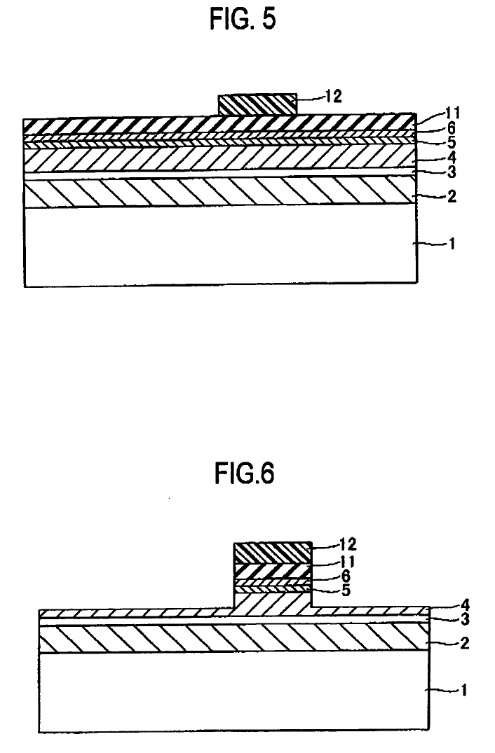

FIGS. 5 to 8 are sectional views for describing a process of manufacturing a nitride semiconductor laser device of the first embodiment of FIG. 1. Next, with reference to FIGS. 1 to 8, the process of manufacturing a nitride semiconductor laser device of the first embodiment is described.

First, as shown in FIG. 5, using a MOCVD (Metal Organic Chemical Vapor Deposition) technique, the n-type clad layer 2, the active layer 3, the p-type clad layer 4 and the p-type contact layer 5 are developed in sequence on a main surface of the n-type GaN substrate. The n-type clad layer 2 is configured of AlₓGa₁₋ₓN (x=0.07), and has a thickness of about 400 nm, the active layer 3 is of MQW structure, the p-type clad layer 4 has a thickness of about 400 nm, and is configured of AlₓGa₁₋ₓN (x=0.07) doped with Mg, and the p-type contact layer 5 is configured of InₓGa₁₋ₓN (x=0.02) doped with Mg. When developing the active layer 3, a plurality of well layers 3a (refer to FIG. 2) and a plurality of barrier layers 3b (refer to FIG. 2) are alternately developed. Each of the well layers 3a is configured of InₓGa₁₋ₓN (x=0.15), and has a thickness of about 3 nm, and each of the barrier layers 3b is configured of InₓGa₁₋ₓN (x=0.02), and has a thickness of about 20 nm. Thereafter, using an electron beam evaporation technique, the p-side ohmic is electrode 6, and a SiO₂ layer 11 of about 300 nm in thickness, are formed on the p-type contact layer 5. Note that, in the first embodiment, when forming the p-side ohmic electrode 6, the Si layer 6a (refer to FIG. 3) having a thickness of about 1 nm and the Pd layer 6b (refer to FIG. 3) having a thickness of about 20 nm are formed in sequence. At this time, since the Si layer 6a is formed using the electron beam evaporation technique, the Si layer 6a is formed as amorphous silicon. Then, using a photolithographic technique, a resistor 12 is formed on a predetermined region of the SiO₂ layer 11.

Subsequently, as shown in FIG. 6, with the resistor 12 disposed as a mask, a predetermined region halfway into the p-type clad layer 4 from an upper surface of the SiO₂ layer 11is removed using an RIE (Reactive Ion Etching) technique, and thereby, a portion of a surface of the p-type clad layer 4 is exposed. Thus, a flat portion and a convex portion are formed on the p-type clad layer 4; and concurrently, a ridge portion including the convex portion of the p-type clad layer 4 and the p-type contact layer 5 on the convex portion, is formed. In this case, the SiO₂ layer 11 and the p-side ohmic electrode 6 are removed using an RIE technique employing CF₄ gas; and the p-type contact layer 5 and the p-type clad layer 4 are removed using an RIE technique employing Cl₂ gas. Thereafter, the resistor 12 and the SiO₂ layer 11 are removed through a process using removal liquid and a process using a buffered HF.

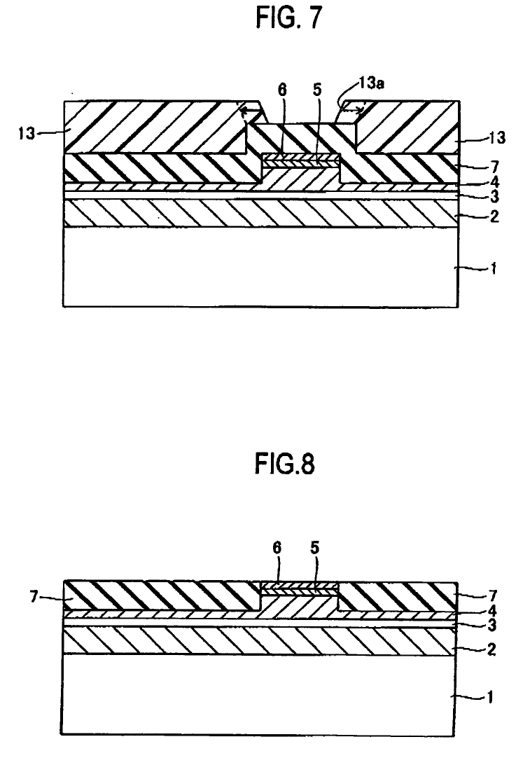

Next, as shown in FIG. 7, using a plasma CVD technique, a current block layer 7 configured of SiO₂ of about 300 nm in thickness is formed to cover the entire surface. Thereafter, using the photolithographic technique, a resistor 13 having an opening 13a is formed on a portion of the current block layer 7 located on the p-side ohmic electrode 6. In this case, the opening 13a of the resistor 13 is formed such that the opening 13a has a tilted shape, which is made gradually larger in an upward direction. With the resistor 13 disposed as a mask, a portion of the current block layer 7, which corresponds to the opening 13a of the resistor 13, is etched using the RIE technique employing CF₄ gas. At this time, the width of the opening 13a of the resistor 13 is made gradually larger as etching is progressed as shown with an arrow in FIG. 7. Hence, an upper surface of the current block layer 7 is flattened Then, the resistor 13 is removed, resulting in a state shown in FIG. 8.

Thereafter, in the first embodiment, as shown in FIG. 1, using the electron beam evaporation technique, a Ti layer (not shown) having a thickness of about 100 nm, a Pd layer (not shown) having a thickness of about 150 nm, and an Au layer (rot shown) having a thickness of about 300 nm, are deposited in sequence from the side of the p-side ohmic electrode 6, on the predetermined region of an upper surface of the p-side ohmic electrode 6, and of the current block layer 7. Thereby, the pad electrode 8 is formed thereon. Then, the n-type GaN substrate 1 is formed to have a thickness of about 100 nm by means of polishing and etching.

Thereafter, in the first embodiment, using the electron beam evaporation technique, the Si layer 9a (refer to FIG. 4) having a thickness of about 1 nm, the Al layer 9b (refer to FIG. 4) having a thickness of about 6 nm, and the Pd layer 9c (refer to FIG. 4) having a thickness of about 30 nm, are deposited in sequence from the side of the n-type GaN substrate 1, on a predetermined region of an lower surface (a reverse surface) of the n-type GaN substrate 1. Thereby, the n-side ohmic electrode 9 is formed thereon. At this time, since the Si layer 9a is formed using the electron beam evaporation technique, the Si layer 9a is formed as amorphous silicon. Then, a pad electrode 10, which is farmed of an Au layer having a thickness of about 300 nm, is formed on a lower surface of the n-side ohmic electrode 9 by use of the electron beam evaporation technique.

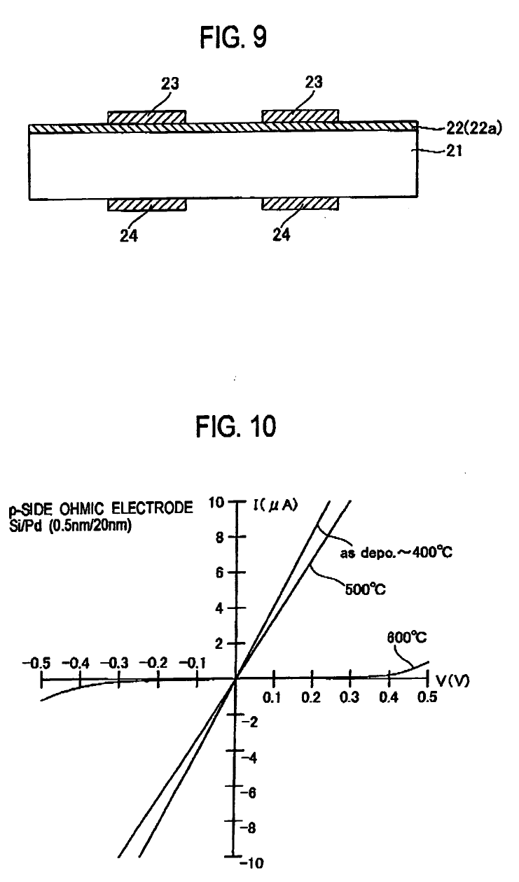

FIGS. 9 to 24 are views for describing an experiment conducted for validating an effect of the nitride semiconductor laser device of the first embodiment, shown in FIG. 1. Next, referring to FIGS. 9 to 24, a description will be given for an experiment conducted for validating an effect of the nitride semiconductor laser device of the above first embodiment. In this experiment, a sample (refer to FIG. 9) for measuring the respective ohmic characteristics of a p-side ohmic electrode and an n-side ohmic electrode is evaluated. As to a method of making the sample, first, a p-side InGaN layer 22 of about 3 nm in thickness is formed on an n-side GaN substrate 21 by use of the MOCVD technique as shown in Pig. 9. Then, using a vacuum evaporation method, two pieces of p-side ohmic electrodes 23 are formed on the p-side InGaN layer 22 with a predetermined interval. Thereafter, using the vacuum evaporation method, two pieces of n-side ohmic electrodes 24 are formed on a lower surface of the n-type GaN substrate 21 with a predetermined interval.

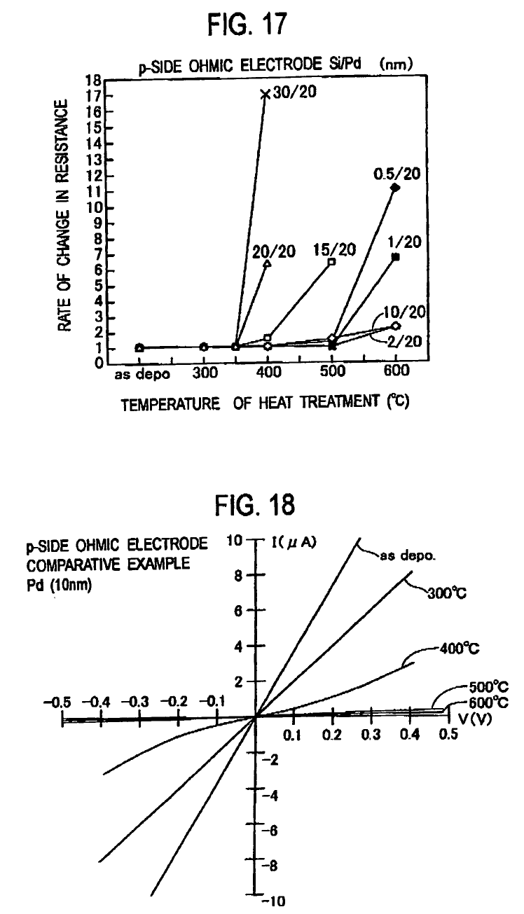

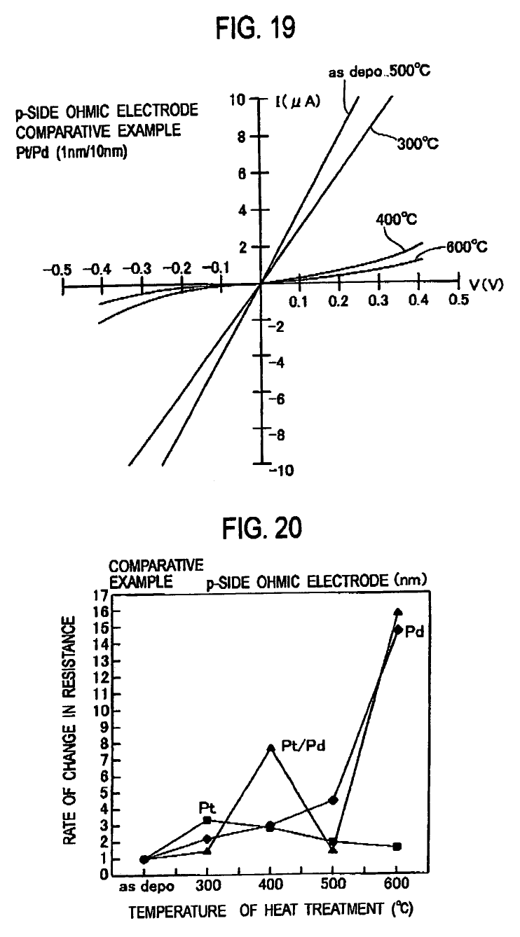

First, with reference to FIGS. 9 to 21, a description will be given for an experiment conducted for validating an effect of the p-side ohmic electrode of the nitride semiconductor laser device of the above first embodiment. In the experiment, the p-side ohmic electrode 23 is configured to include a Si layer, which contacts with the p-side InGaN layer 22, and a Pd layer of about 20 nm in thickness located above the Si layer. The thickness of the Si layer is varied. More precisely, Si layers are formed to have approximate thicknesses of 0.5 nm, 1 nm, 2 nm, 10 nm, 15 nm, 20 nm, and 30 nm, respectively, for samples to be fabricated. In addition, as comparative examples, the following samples are fabricated. The samples are: samples in which the p-side ohmic electrode 23 is formed of only a Pd layer of about 10 nm in thickness; samples in which the p-side ohmic electrode 23 is formed of a Pt layer of about 1 nm in thickness provided in place of the Si layer, and in which the Pd layer of about 10 nm in thickness formed on the Pt layer; and samples in which the p-side ohmic electrode 23 is formed of the Pt layer only. Current-voltage characteristics (I-V characteristics) are measured after making the above samples, as well as after performing heat treatment on the samples at predetermined temperatures (approximately at 300° C., 350° C., 400° C., 500° C., and 600° C.) for about 5 minutes. Results thereof are shown in FIGS. 10 to 16, and FIGS. 18 and 19. In addition, after making the samples, a value of resistance in a state where heat treatment is not performed (as depo. state) is set as a standard for normalization, and rates of change in resistance are calculated. Results thereof are shown in FIGS. 17 and 20. Note that current-voltage characteristics are measured using a curve tracer, which is one of semiconductor characteristics measuring devices. Hereinafter, results of measurement thereof are described.

It was revealed that, in a case where the p-side ohmic electrode 23 is configured to include a Si layer, which contacts with the p-type InGaN layer 22, and which has a thickness equal to or more than 0.5 nm and equal to or less than 30 nm, the ohmic characteristics of the p-side ohmic electrode 23 are not deteriorated when performing beat treatment at a temperature not greater than about 350° C., as is clear from I-V characteristics shown in FIGS. 10 to 16 and rates of change in resistance shown in FIG. 17. Furthermore, it has been revealed that, in a case where the thickness of the Si layer is not less than 15 nm, the ohmic characteristics are deteriorated when performing heat treatment at a temperature of about 400° C., as is clear from the I-V characteristics shown in FIGS. 14 to 16 and the rates of change in resistance shown in FIG. 17. In contrast, it has been revealed that, in a case where the p-side ohmic electrode 23 is formed of only a Pd layer having a thickness of about 10 nm, the ohmic characteristics of the p-side ohmic electrode 23 are deteriorated, and that the deterioration of the ohmic characteristics is further progressed as the temperature of heat treatment is increased even when performing heat treatment at a temperature of about 300° C., as is clear from the I-V characteristics shown in FIG. 18 and the rates of change in resistance shown in FIG. 20. Moreover, it has also been revealed that, in a case where the p-side ohmic electrode 23 is formed of a Pt layer and a Pd layer without including a Si layer, the ohmic characteristics of the p-side ohmic electrode 23 are deteriorated and come to an unstable state, in which resistance increases or decreases in response to temperatures of heat treatment, even when performing heat treatment at a temperature of about 300° C., as is clear from the I-V characteristics shown in FIG. 19 and the rates of change in resistance shown in FIG. 20. Furthermore, it has been revealed that, in a case where p-side ohmic electrode 23 is formed of a Pt layer only, the ohmic characteristics of the p-side ohmic electrode 23 are deteriorated when performing heat treatment at temperatures of about 300° C. and about 400° C., as is clear from the rates of change in resistance shown in FIG. 20.

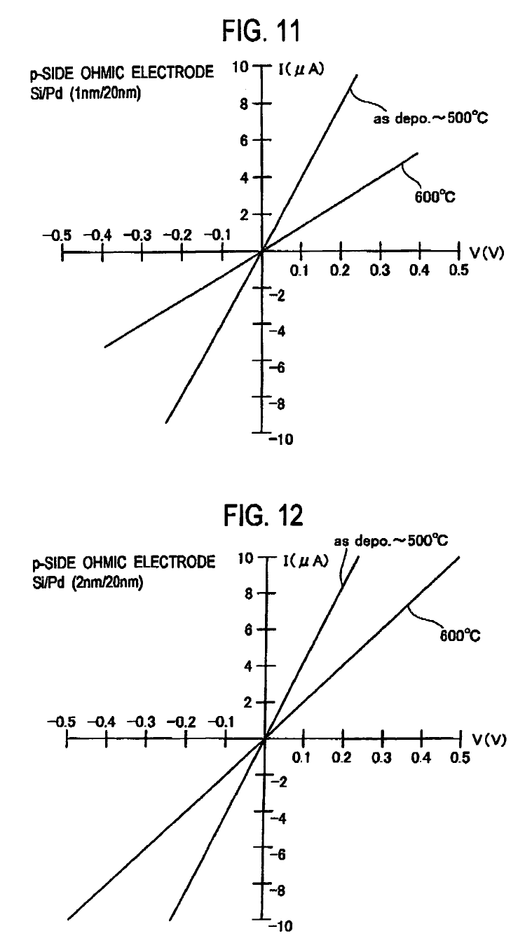

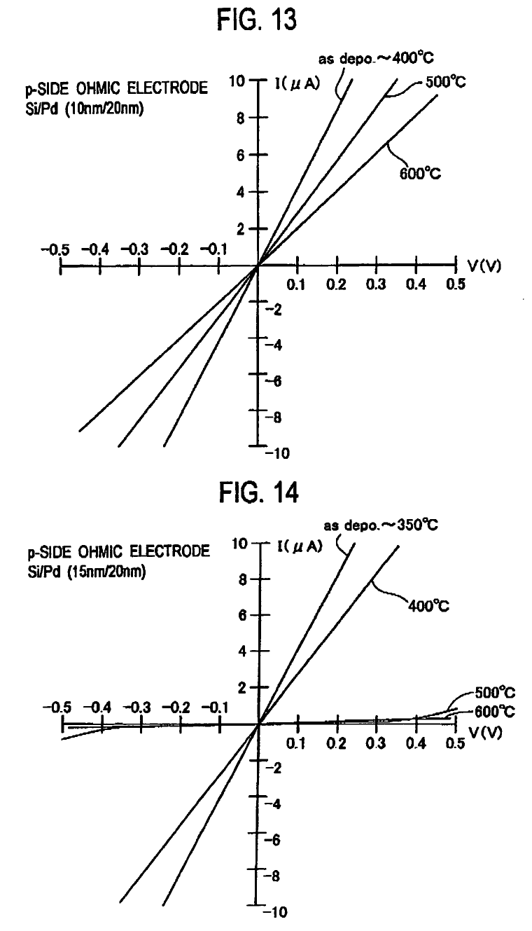

Hereinafter, a detailed description will be given for I-V characteristics corresponding to the respective thicknesses of Si layers of the first embodiment, and for I-V characteristics of those of the comparative examples. When the thickness of the Si layer is about 0.5 nm, as shown in FIG. 10, the ohmic characteristics of the p-side ohmic electrode 23, which is obtained at a time when heat treatment is performed at a temperature not greater than about 400° C., are the same as those where heat treatment is not performed (as depo.), and are not deteriorated. On the other hand, when performing heat treatment at a temperature of about 500° C., resistance (R=V/I) somewhat increases, and the ohmic characteristics of the p-side ohmic electrode 23 are somewhat deteriorated. Additionally, when performing heat treatment at a temperature of about 600° C., the ohmic characteristics of the p-side ohmic electrode 23 are deteriorated to a large extent, and an ohmic contact is not obtained. Moreover, in a case where the thickness of the Si layer is about 1 nm, as shown in FIG. 11, when performing heat treatment at a temperature not greater than about 500° C., the ohmic characteristics of the p-side ohmic electrode 23 are the same as those where heat treatment is not performed (as depo.), and are not deteriorated. When performing heat treatment at a temperature of about 600° C., resistance increases, and the ohmic characteristics of the p-side ohmic electrode 23 are deteriorated. In a case where the thickness of the Si layer is about 2 nm, as shown in FIG. 12, when performing heat treatment at a temperature not greater than about 500° C., the ohmic characteristics of the p-side ohmic electrode 23 are the same as those where heat treatment is not performed (as depo.), and are not deteriorated. When performing heat treatment at a temperature of about 600° C., resistance increases, and the ohmic characteristics of the p-side ohmic electrode 23 are deteriorated. In a case where the thickness of the Si layer is about 10 nm, as shown in FIG. 13, when performing heat treatment at a temperature not greater than about 400° C., the ohmic characteristics of the p-side ohmic electrode 23 are the same as those where heat treatment is not performed (as depo.), and are not deteriorated. When performing heat treatment at a temperature of about 500° C., a resistance somewhat increases, and the ohmic characteristics of the p-side ohmic electrode 23 are somewhat deteriorated. When performing heat treatment at a temperature of about 600° C., a resistance further increases, and the ohmic characteristics of the p-side ohmic electrode 23 are further deteriorated.

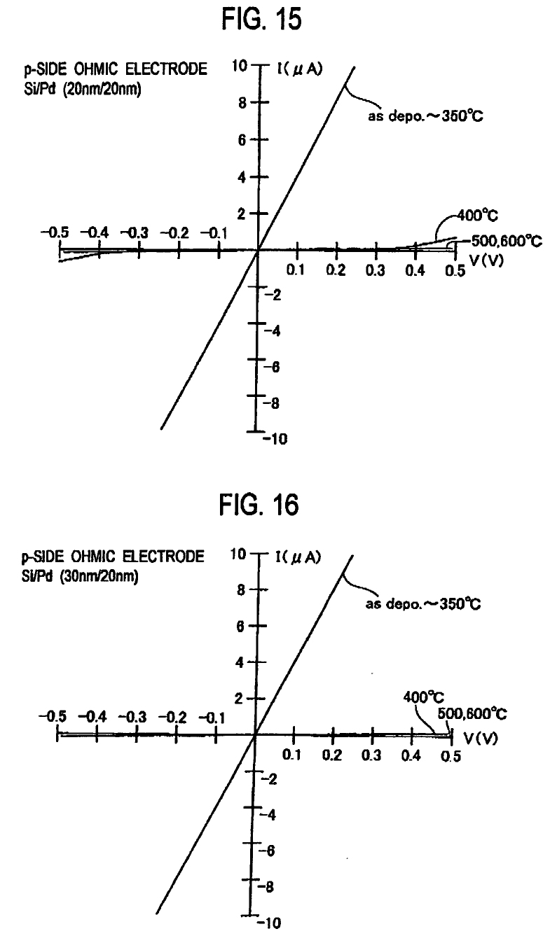

In a case where the thickness of the Si layer is about 15 nm, as shown in FIG. 14, when performing heat treatment at a temperature not greater than 350° C., the ohmic characteristics of the p-side ohmic electrode 23 are the same as those where beat treatment is not performed (as depo.), and are not deteriorated. When performing heat treatment at a temperature of about 400° C., a resistance somewhat increases, and the ohmic characteristics of the p-side ohmic electrode 23 are somewhat deteriorated. When performing heat treatment at temperatures of about 500° C. and about 600° C., the ohmic characteristics of the p-side ohmic electrode 23 are deteriorated to a large extent. In a case where the thickness of the Si layer is about 20 nm, as shown in FIG. 15, when performing heat treatment at a temperature not greater than about 350° C., the ohmic characteristics of the p-side ohmic electrode 23 are the same as those where heat treatment is not performed (as depo.), and are not deteriorated. When performing heat treatment at a temperature of about 400° C. to about 600° C., the ohmic characteristics are deteriorated to a large extent. Furthermore, in a case where the thickness of the Si layer is about 30 nm, as shown in FIG. 16, when performing heat treatment at a temperature not greater than about 350° C., the ohmic characteristics of the p-side ohmic electrode 23 are the same as those where heat treatment is not performed (as depo.), and are not deteriorated. When performing heat treatment at a temperature of about 400° C. to about 600° C., the ohmic characteristics are deteriorated to a large extent.

In contrast, in the case of the comparative example where the p-ride ohmic electrode 23 is formed only of a Pd layer of about 10 nm in thickness, as shown in FIG. 18, even when performing heat treatment at a temperature of about 300° C., resistance increases, and the ohmic characteristics of the p-side ohmic electrode 23 are deteriorated to a large extent. When performing heat treatment at a temperature of about 400° C., the ohmic characteristics of the p-side ohmic electrode 23 are deteriorated to a large extent, and an ohmic contact is not obtained. When performing heat treatment at a temperature of about 500° C. and about 600° C., the ohmic characteristics of the p-side ohmic electrode 23 are further deteriorated. In a case where the p-side ohmic electrode 23 is formed of the Pt layer and the Pd layer, as shown in FIG. 19, even when performing heat treatment at a temperature of about 300° C., resistance somewhat increases, and the ohmic characteristics of the p-side ohmic electrode 23 are somewhat deteriorated. Moreover, when performing heat treatment at a temperature of about 400° C., the ohmic characteristics of the p-side ohmic electrode 23 are deteriorated to a large extent, and an ohmic contact is not obtained. Furthermore, when performing heat treatment at a temperature of about 500° C., the ohmic characteristics are restored, and the obtained ohmic characteristics are the same as those at the time after making the samples. Moreover, when performing heat treatment at a temperature of 600° C., the ohmic characteristics of the p-side electrode 23 are deteriorated to a large extent, and an ohmic contact is not obtained.

Furthermore, with the Si layer included in the p-side ohmic electrode 23, when performing heat treatment at a temperature not greater than about 350° C., the ohmic characteristics of the p-side ohmic electrode 23 are not deteriorated. A reason for this may be explained as follows. More specifically, the p-side ohmic electrode 23 is configured to include a Si layer and a Pd layer. The Si layer has a thickness of about 0-5 nm to about 30 nm, and is formed such that the Si layer contacts with a main surface of the p-type InGaN layer 22. The Pd layer has a thickness of about 20 nm, and is formed on the Si layer. Accordingly, unlike the case where the Pd layer is formed directly on a main surface of the p-type InGaN layer 22 having a large band-gap (band-gap: about 3.5 eV), a Pd layer is formed with a Si layer, which has a small band-gap (band-gap: about 1.1 eV), and which is interposed between the Pd layer and the p-type InGaN layer 22. In this way, it is possible to cause the p-side ohmic electrode to form a more favorable ohmic contact with the p-type InGaN layer 22, and to maintain the favorable ohmic contact even when the heat of about 250° C. to about 350° C. is applied.

By forming the Si layer using the vacuum evaporation method as described above, the Si layer is formed as amorphous silicon. In such a Si layer configured of amorphous silicon, a large number of defects are contained. Electrons, therefore, can pass through the large number of defects. Accordingly, it is considered that, since electrons can easily pass between the Pd layer and the p-type InGaN layer 22 with the Si layer interposed, the p-side ohmic electrode 23 is allowed to easily form an ohmic contact with the p-side InGaN layer 22.

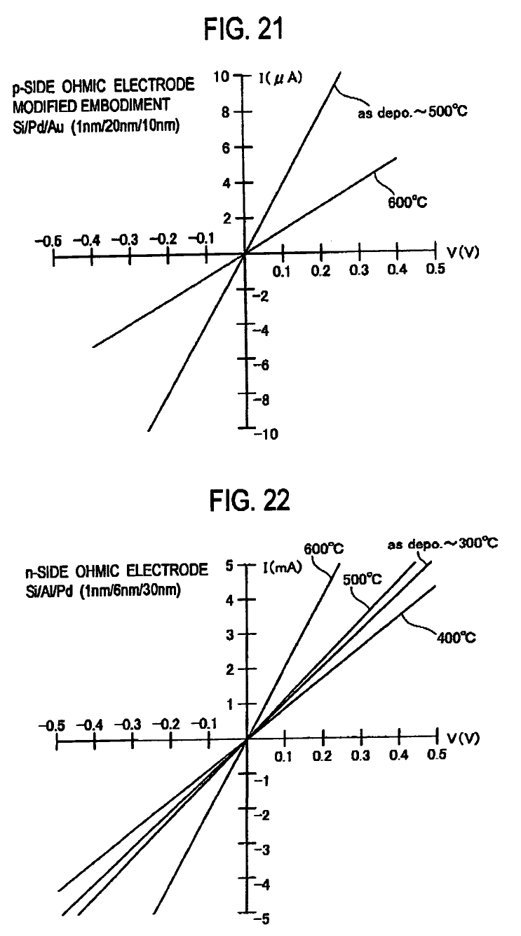

Note that, as a modified example of the first embodiment, current-voltage characteristics are measured also for a case where the p-side ohmic electrode 23 is configured to include a Si layer of about 1 nm in thickness which contacts with the p-type InGaN layer 22; a Pd layer of about 20 nm in thickness formed on the Si layer; and an Au layer of about 10 nm in thickness formed on the Pd layer. As a result, as shown in FIG. 21, the current-voltage characteristics obtained for the above case are the same as those obtained for the case (refer to FIG. 11) where the p-side ohmic electrode 23 is configured to include a Si layer, which has a thickness of about 1 nm, and which contacts with the p-type InGaN layer 22; and a Pd layer of about 20 nm in thickness formed on the Si layer. Hence, it has been revealed that there is no difference between the ohmic characteristics in the case where the Au layer is formed on the Pd layer of the p-side ohmic electrode 23 and the ohmic characteristics in the case where the Au layer is not formed thereon.

Subsequently, referring to FIG. 9 and FIGS. 22 to 24, a description will be given for an experiment conducted for validating an effect of an n-side ohmic electrode of the nitride semiconductor laser device of the aforementioned first embodiment. In this experiment, an n-side ohmic electrode 24 of the sample corresponding to the first embodiment shown in FIG. 9 is configured to include a Si layer of about 1 nm in thickness which contacts with a reverse side (a lower surface) of the n-side GaN substrate 21; an Al layer of about 6 nm in thickness formed on a lower surface of the Si layer; and a Pd layer of about 30 nm in thickness formed on a lower surface of the Al surface. Moreover, as a comparative example, the n-side ohmic electrode 24 is configured to include an Al layer of about 6 in thickness which contacts with a reverse side (a lower side) of the n-side GaN substrate 21, and a Pd layer of about 30 nm in thickness formed on a lower surface of the Al layer. Current-voltage characteristics (I-V characteristics) are measured and rates of change in resistance are calculated in the same manner as that in the case of the experiment conducted for validating the effect of the above p-side ohmic electrode. The results thereof are shown in FIGS. 22 to 24.

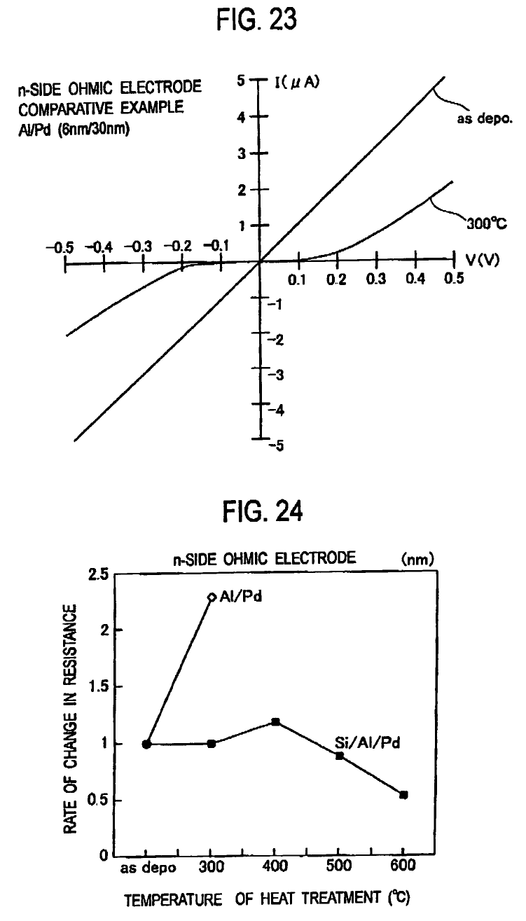

In a case of a sample corresponding to the first embodiment where the n-side ohmic electrode 24 is formed of the Si layer, the Al layer, and the Pd layer, when performing heat treatment at a temperature of about 300° C., the ohmic characteristics of the n-side ohmic electrode 24 are the same as those where heat treatment is not performed (as depo.), and are not deteriorated, as shown in FIGS. 22 to 24. On the other hand, when performing heat treatment at a temperature of about 400° C., resistance somewhat increases, and the ohmic characteristics of the n-side ohmic electrode 24 are somewhat deteriorated. Moreover, when performing heat treatment at a temperature of about 500° C., more favorable ohmic characteristics are obtained than those at the time after making the sample. When performing heat treatment at a temperature of about 600° C., even more favorable ohmic characteristics are obtained than those at the time after making the sample. On the other hand, in a case of the sample of the comparative example where the n-side ohmic electrode 24 is formed of the Al layer and the Pd layer, as shown in FIGS. 23 and 24, even when performing heat treatment at a temperature of about 300° C., the ohmic characteristics of the n-side ohmic electrode 24 are deteriorated to a large extent, and an ohmic contact is not obtained. Accordingly, it has been revealed that, in the case of the sample of the first embodiment where the n-side ohmic electrode 24 is formed of the Si layer, the Al layer, and the Pd layer, deterioration, due to heat treatment, of the ohmic characteristics of the n-side ohmic electrode 24 is suppressed compared with the case of the sample of the comparative example where the n-side ohmic electrode 24 is formed of the Al layer and the Pd layer.

Incidentally, the n-side ohmic electrode 24 is formed to include the Si layer, and thereby, deterioration of the ohmic characteristics of the n-side ohmic electrode 24 is suppressed. A reason for this is considered to be the same as that for the case of the p-side ohmic electrode 23.

### Second Embodiment

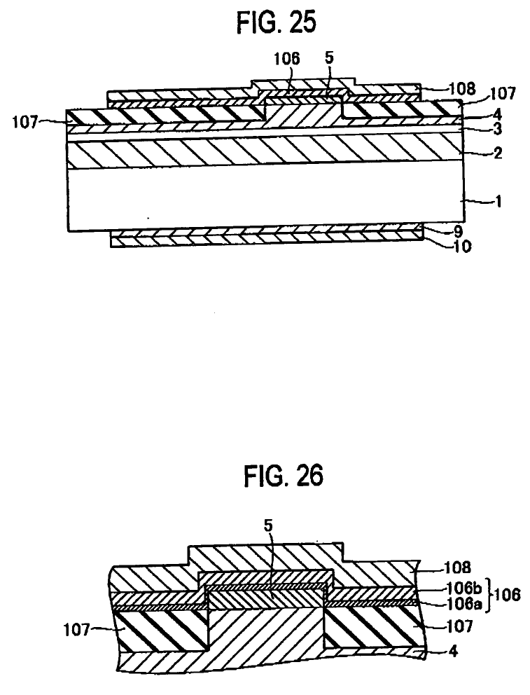

FIG. 25 is a sectional view showing a structure of a nitride semiconductor laser device (nitride semiconductor device) of a second embodiment of the present invention. FIG. 26 is a view for describing in detail the structure of the nitride semiconductor laser device of the second embodiment shown in FIG. 25. With reference to FIGS. 25 and 26, in the second embodiment, a description will be given for a case where, unlike that in the first embodiment, the thickness of a Si layer of a p-side ohmic electrode is increased to about 2 nm.

In the nitride semiconductor laser device of the second embodiment, as shown in FIG. 25, an n-type GaN substrate 1, an n-type clad layer 2, an active layer 3, and a p-type clad layer 4, each of which has the same configuration and thickness as those of the first embodiment, are formed. Moreover, on a convex portion of the p-type clad layer 4, as in the first embodiment, a p-type contact layer 5 of about 10 nm in thickness is formed and the p-type contact layer5 is configured of InₓGa₁₋ₓN (x=0.02) doped with Mg. Furthermore, a current block layer 107 configured of SiO₂ is firmed to cover a side surface of the convex portion, and an upper surface of a flat portion of the p-type clad layer 4.

Moreover, a p-type ohmic electrode 106 is formed to cover a predetermined region on an upper surface of the current block layer 107 and upper and side surfaces of the p-type contact layer 5. Incidentally, the p-type ohmic electrode 106 is one example of the “ohmic electrode” of the present invention. In this event, in the second embodiment, as shown in FIG. 26, the p-side ohmic electrode 106 is configured to include a Si (silicon) layer 106a and a Pd layer 106b. The Si layer 106a is configured of amorphous silicon, has a thickness of about 2 nm, and is formed such that the Si layer 106a contacts with a surface of the p-type contact layer 5. The Pd layer 106b has a thickness of about 20 nm, and is formed on an upper surface of the Si layer 106a. The Si layer 106a and the Pd layer 106b are disposed in the above sequence from the side of the p-type contact layer 5. That is, in the second embodiment, the thickness of the Si layer 106a of the p-side ohmic electrode 106 is set to 2 nm, which is different from that (1 nm) of the Si layer 6a of the p-side ohmic electrode 6 of the first embodiment. Configurations of the p-side ohmic electrode 106 of the second embodiment other than that described above are the same as those of the p-side ohmic electrode 6 of the first embodiment incidentally, the Pd layer 106b is one example of the “first metal layer” of the present invention.

On the p-side ohmic electrode 106, a pad electrode 108 is formed as shown in FIG. 25. Incidentally, the pad electrode 108 is one example of the “second metal layer” of the present invention. This pad electrode 108 is configured of a Ti layer (not shown) of about 100 nm in thickness and an Au layer (not shown) of about 1 nm in thickness. The Ti later and the Au layer are disposed in the above sequence from the side of the p-side ohmic electrode 106.

In addition, on a predetermined region of a lower surface (reverse side) of the n-side GaN substrate 1, an n-side ohmic electrode 9 and a pad electrode 10, each of which has the same configuration and thickness as those of the aforementioned first embodiment, are formed. That is, as shown in FIG. 4, the n-side ohmic electrode 9 is configured to include a Si layer 9a configured of amorphous silicon o f about 1 nm in thickness which contacts with a lower surface of the n-type GaN substrate 1; an Al layer 9b of about 6 nm in thickness; and a Pd layer 9c of about 100 nm in thickness. The Si layer 9a, the Al layer 9b and the Pd layer 9c are disposed in the above sequence from the side of the n-type GaN substrate 1.

Next, a description will be given for results of measurement of forward voltages at a time when a forward current of 20 mA flows in the nitride semiconductor laser device of the second embodiment. In the nitride semiconductor laser device of the second embodiment, as in the case of the first embodiment, a forward voltage is 4.4 V after the wafer process, and is 4.2 V after the assembling process. From these results, it has been confirmed that, even in the case where the thickness of the Si layer 106a of the p-side ohmic electrode 106 is increased to about 2 nm, which is different from that of the first embodiment, deterioration of the ohmic characteristics between the p-side ohmic electrode 106 and the p-type contact layer 5 can be suppressed, as in the first embodiment, the deterioration being caused by applying the heat of about 250° C. to about 350° C.

As described above, in the second embodiment, the p-side ohmic electrode 106 is configured to include the Si (silicon) layer 106a of about 2 nm in thickness which contacts with a main surface of the p-type contact layer 5; and the Pd layer 106b of about 20 nm in thickness formed on the Si layer 106a; and the n-side ohmic electrode 9 is configured to include the Si layer 9a of about 1 nm in thickness which contacts with a lower surface of the n-type GaN substrate 1; the Al layer 9b of about 6 nm in thickness formed on a lower surface of the Si layer 9a; and the Pd layer 9c of about 100 nm in thickness formed on the Al layer 9b. Hence, as in the first embodiment, even when the heat of about 250° C. to about 350° C. is applied during soldering in the assembling of the p-side ohmic electrode 106 and the n-side ohmic electrode 9 after the forming of the same, ohmic characteristics are not deteriorated easily, due to the effects of the Si layers 106a and 9a, which rerspectively contact with the main surfaces of the p-type contact layer 5 and with the n-type GaN substrate 1. Thus, deterioration, due to heat, of the ohmic characteristics between the p-side ohmic electrode 106 and the p-type contact layer 5, and between the n-side ohmic electrode 9 and the n-type GaN substrate 1, can be suppressed.

Incidentally, other effects of the second embodiment are the same as those of the first embodiment.

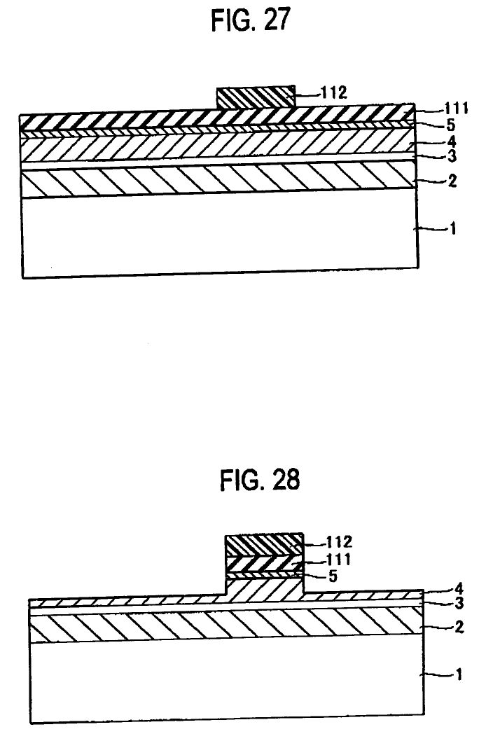

FIGS. 27 to 30 are sectional views for describing a process of manufacturing the nitride semiconductor laser device of the second embodiment. Referring to FIGS. 25 to 30, the process of manufacturing the nitride semiconductor laser device of the second embodiment is described.

First, using the same process as that of the first embodiment shown in FIG. 5, the n-type clad layer 2, the active layer 3, the p-type clad layer 4, and the p-type contact layer 5 are developed in sequence on the n-type GaN substrate 1. Thereafter, as shown in FIG. 27, a SiO₂ layer 111 having a thickness of about 300 nm is formed on the p-type contact layer 5 by use of the electron beam evaporation technique. Then, using the photolithographic technique, a resistor 112 is formed on a predetermined region of the SiO₂ layer 111.

Subsequently, as shown in FIG. 28, with the resistor 112 disposed as a mask, a predetermined region halfway into the p-type clad layer 4 from an upper surface of the SiO₂ layer 111is removed using the RIE (Reactive Ion Etching) technique. Thereby, a portion of a surface of the p-type clad layer 4 is exposed. Thus, a flat portion and a convex portion are formed on the p-type clad layer 4; and a ridge portion, which includes the convex portion of the p-type clad layer 4 and the p-type contact layer 5 on the convex portion thereof, is formed. In this case, as in the first embodiment, the SiO₂ layer 111 is removed using the RIE technique employing CF₄ gas; and the p-type contact layer 5 and the p-type clad layer 4 are removed using the RIE technique employing Cl₂ gas. Thereafter, the resistor 112 and the SiO₂ layer 111 are removed through the process using removal liquid and the process using the buffered HF.

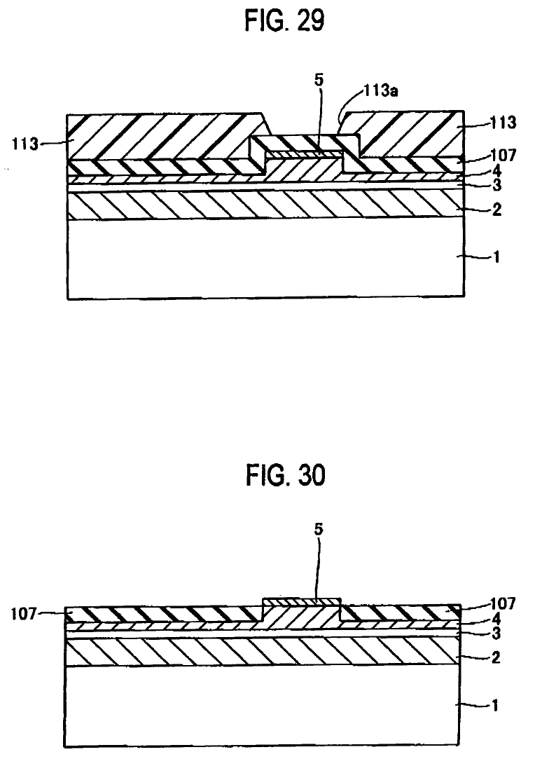

Next, as shown in FIG. 29, using the plasma CVD technique, the current block layer 7 configured of SiO₂ is formed to cover the entire surface. Thereafter, as in the process of forming the resistor 13 in the aforementioned first embodiment, using the photolithographic technique, a resistor 113 with an opening 113a is formed on a portion of the current block layer 107, which is located on the p-type contact layer 5. Subsequently, with the resistor 113 disposed as a mask, using the same process as that of the first embodiment, a portion of the current block layer 7, which corresponds to the opening 113a of the resistor 113, is etched using the RIE technique employing CF₄ gas. Then, the resistor 113 is removed, resulting in a state shown in FIG. 30.

Thereafter, as shown in FIG. 25, using the electron beam evaporation technique, the p-type ohmic electrode 106 is formed on the predetermined regions respectively of an upper surface of the p-type contact layer 6 and of the current block layer 107.

Furthermore, in the second embodiment, when forming the p-type ohmic electrode 106, the Si layer 106a (refer to FIG. 26) having a thickness of about 2 nm, and the Pd layer 106b (refer to FIG. 26) having a thickness of about 20 nm, are developed in sequence. At this time, since the Si layer 106a is formed using the electron beam evaporation technique, the Si layer 106a is formed as amorphous silicon.

Thereafter, using the electron beam evaporation technique, on the p-side ohmic electrode 106, a Ti layer (not shown) of about 100 nm in thickness, and an Au layer (not shown) of about 1 μm in thickness are deposited in sequence from the side of the p-side ohmic electrode 106. Thereby, the pad electrode 108 is formed thereon. Then, using the same process as that of the first embodiment, the n-side ohmic electrode 9, which is formed of the Si layer 9a (refer to FIG. 4), the Al layer 9b (refer to FIG. 4), and the Pd layer 9c (refer to FIG. 4), and the pad electrode 10 configured of Au layer, are formed on a predetermined region of a lower surface (reverse surface) of the n-type GaN substrate 1.

### Third Embodiment

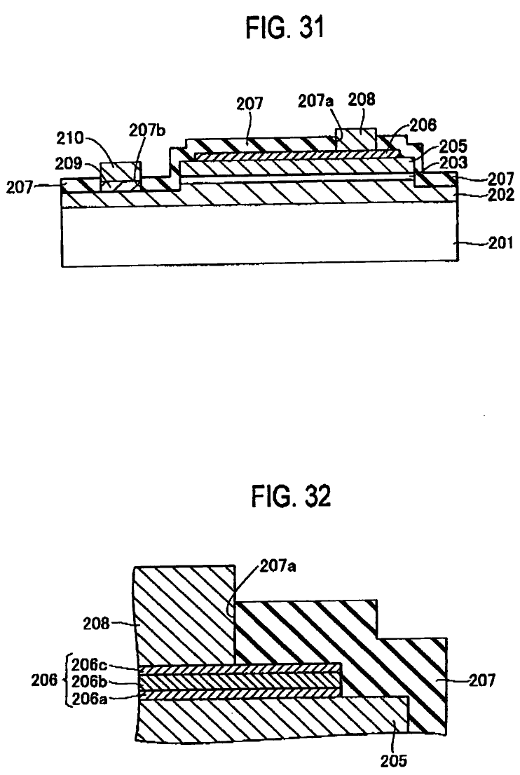

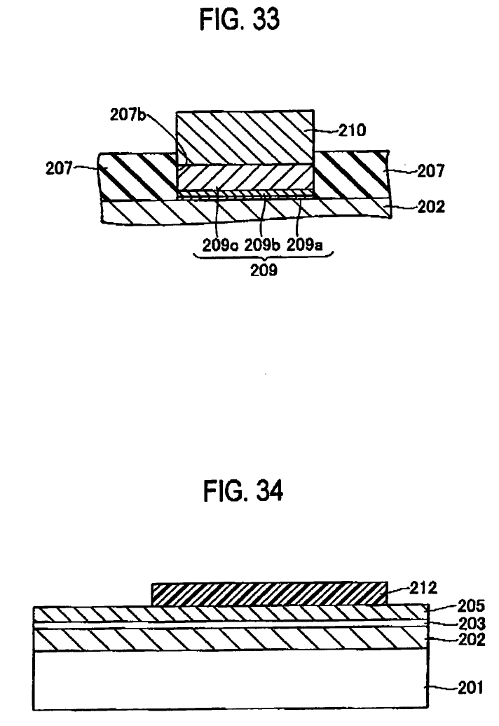

FIG. 31 is a sectional view showing a structure of a nitride semiconductor light-emitting diode device (a nitride semiconductor device) of a third embodiment of the present invention. FIGS. 32 and 33 are views for describing in detail the structure of the nitride semiconductor light-emitting diode device of the third embodiment shown in FIG. 31. In the third 15 embodiment, with reference to FIGS. 31 to 33, a description will be given for a case where, unlike the first embodiment, a p-side ohmic electrode is formed on a p-type contact layer configured of GaN, and where the p-side ohmic electrode is configured of a Si layer, a Pd layer, and a Ti layer.

In the nitride semiconductor light-emitting diode device of the third embodiment, as shown in FIG. 31, an n-type clad layer 202 configured of GaN, having a thickness of about 400 nm, is formed on a sapphire substrate 201. Incidentally, the n-type clad layer 202 is one example of the “n-type nitride semiconductor device” of the present invention. An active layer 203 of the MQW configuration is formed on a predetermined region of the n-type clad layer 202. In the MQW configuration for the active layer 203, the layers of the same configuration and thickness as those of the active layer 3 of the first embodiment, is disposed.

In this event, in the third embodiment, on the active layer 203, a p-type contact (clad) layer 205 of about 400 nm in thickness configured of GaN doped with Mg is formed. Incidentally, the p type contact layer 205 is one example of the “p-type nitride semiconductor device” of the present invention. A predetermined region halfway into the n-type clad layer 202 from an upper surface of the p-type contact layer 205 is removed.

Moreover, on a predetermined region of the p-type contact layer 205, a p-type ohmic electrode 206, which has a function to transmit light, is formed. Incidentally, the p-type ohmic electrode 206 is one example of the “ohmic electrode” of the present invention In addition, in the third embodiment, as shown in FIG. 32, the p-side ohmic electrode 206 is configured of a Si (silicon) layer 206a of about 1 nm in thickness which contacts with a surface of the p-type contact layer 205; a Pd layer 206b of about 5 nm in thickness; and a Ti layer 206c of about 1 nm in thickness. The Si layer 206a, the Pd layer 206b and the Ti layer 206c are disposed in the above sequence from the side of the p-type contact layer 205. Incidentally, the Pd layer 206b is one example of the “first metal layer” of the present invention.

Moreover, a surface protective film 207 configured of SiO₂ is formed to cover the p-side ohmic electrode 206 and the n-type clad layer 202. This surface protective film 207 has an opening 207a on a predetermined region of the p-side ohmic electrode 206, and an opening 207b on a predetermined region of the n-type clad layer 202. In addition, on the p-side ohmic electrode 206, a pad electrode 208 is formed through the opening 207a so that the pad electrode 208 is in contact with the p-type ohmic electrode 206. Incidentally, the pad electrode 208 is one example of the “second metal layer” of the present invention. This pad electrode 208 is configured of a Ti layer (not shown) of about 10 nm in thickness, a Pd layer (not shown) of about 100 nm in thickness, and an Au layer (not shown) of about 300 nm in thickness. The Ti layer, the Pd layer and the Au layer are disposed in the above sequence from the side of the p-type ohmic electrode 206.

Furthermore, on the n-type clad layer 202, an n-side ohmic electrode 209 is formed through the opening 207b so that the n-type ohmic electrode 209 is in contact with the n-type clad layer 202. Incidentally, the n-side ohmic electrode 209 is one example of the “ohmic electrode” of the present invention. As shown in FIG. 33, this n-side ohmic electrode 209 has a Si layer 209a of about 1 nm in thickness configured of amorphous silicon which contacts with a surface of the n-type clad layer 202; an Al layer 209b of about 6 nm in thickness; and a Pd layer 209c of about 100 nm in thickness. Incidentally, the Al layer 209b and the Pd layer 209e are examples of the “first metal layer” of the present invention. In addition, on the n-side ohmic electrode 209, a pad electrode 210 formed of an Au layer, which has a thickness of about 300 nm, is formed, as shown in Pig. 31. Incidentally, the pad electrode 210 is one example of the “second metal layer” of the present invention.

Next, a description will be given for results of measurement of forward voltages at a time when a forward current of about 20 mA flows in the nitride semiconductor light-emitting diode device of the third embodiment- Incidentally, as a comparative example, forward voltages for a conventional nitride semiconductor light-emitting diode device are also measured. It should be noted that a conventional nitride semiconductor light-emitting diode device is formed to include a p-side ohmic electrode, which is farmed of a Pd layer having a thickness of about 2 nm, an Au layer having a thickness of about 4 nm, and an Ni layer having a thickness of about 1 nm; a pad electrode formed on the p-side ohmic electrode and configured of an Au layer having a thickness of about 300 nm; an n-side ohmic electrode configured of an Al layer having a thickness of about 6 nm and a Pd layer having a thickness of about 30 nm; and a pad electrode formed on the n-side ohmic electrode and configured of an Au layer having a thickness of about 300 nm. As a result, in the nitride semiconductor light-emitting diode device of the third embodiment, a forward voltage is about 3.5 V after the wafer process, and is also about 3.5 V after assembling process. In contrast, in the conventional nitride semiconductor light-emitting diode device, a forward voltage is about 3.5 V after the wafer process, and is about 4.0 V after the assembling process. In other words, the results show that, in the conventional nitride semiconductor light-emitting diode device, the forward voltage after the assembling process is increased. On the other hand, in the nitride semiconductor light-emitting diode device of the third embodiment, the forward voltage remains unchanged. From these results, it has been confirmed that, oven in the case where, unlike the case of the first embodiment, the p-side ohmic electrode 206 is formed on the p-side contact layer 205 configured of GaN, as well as where the n-side ohmic electrode 209 is formed on the n-type dad layer 202 configured of GaN, deterioration of the ohmic characteristics between the p-side ohmic electrode 206 and the p-type contact layer 205, and between the n-side ohmic electrode 209 and the n-type clad layer 202, can be suppressed, as in the first embodiment, the deterioration being caused by the heat of about 250° C. to about 350° C. applied during soldering at the time of assembly. Incidentally, transmittance rate of the p-side ohmic electrode 206 is approximately 70%, and is roughly the same as that of a conventional p-side ohmic electrode.

As described above, in the third embodiment, the p-side ohmic electrode 206 is configured to include the Si layer 206a of about 1 nm in thickness which contacts with a main surface of the p-type contact layer 205; the Pd layer 206b of about 5 nm in thickness formed on the Si layer 206a; and the Ti layer 206c of about 1 nm in thickness; and the n-side ohmic electrode 209 is configured to include the Si layer 209a of about 1 nm in thickness which contacts with a main surface of the n-type clad layer 202; the Al layer 209b of about 6 nm in thickness formed on the Si layer 209a; and the Pd layer 209c of about 100 nm in thickness formed on the Al layer 209b. Hence, as in the first embodiment, even when the heat of about 250° C. to about 350° C. is applied during soldering in the assembling of the p-side ohmic electrode 206 and of the n-side ohmic electrode 209 after the forming of the same, ohmic characteristics are not deteriorated easily, due to the effects of the Si layers 206a and 209a, which contact respectively with the main surfaces of the p-type contact layer 205 and the n-type clad layer 202. Thus, deterioration, due to heat, of the ohmic characteristics between the p-side ohmic electrode 206 and the p-type contact layer 205, and between the n-side ohmic electrode 209 and the n-type clad layer 202, can be suppressed. This point has been validated by an experiment to be described later.

Incidentally, other effects of the third embodiment are the same as those of the first embodiment.

FIGS. 34 to 38 are sectional views for describing a process of manufacturing the nitride semiconductor light-emitting diode device of the third embodiment shown in FIG. 31 Referring to FIGS. 31 to 38, the process of manufacturing the nitride semiconductor light-emitting diode device of the third embodiment is described.

First, as shown in FIG. 34, in the third embodiment, using the MOCVD technique, the n-type clad layer 202 of about 400 nm in thickness configured of GaN, the active layer 203 of the MQW structure, and the p-type contact (clad) layer 205 of about 400 nm in thickness configured of GaN doped with Mg, are developed in sequence on the sapphire substrate 201. Note that the active layer 203 is formed in the same way as that for the active layer 3 of the aforementioned first embodiment. Thereafter, using the photolithographic technique, a resistor 212 is formed on a predetermined region of the p-type contact layer 205.

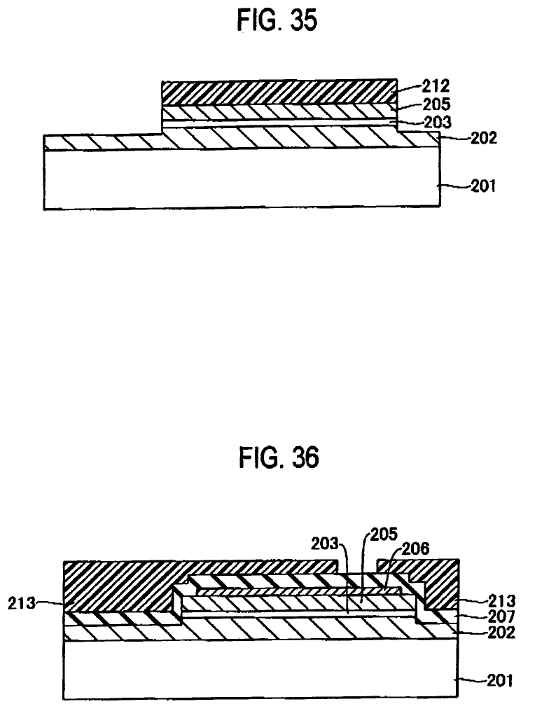

Subsequently, as shown in FIG. 35, with the resistor 212 disposed as a mask, a predetermined region halfway into the n-type clad layer 202 from an upper surface of the p-type contact layer 205 is removed using the RIE technique. Thereby, a portion of a surface of the n-type clad layer 202 is exposed. Thereafter, the resistor 212 is removed.

Subsequently, as shown in FIG. 36, the p-side ohmic electrode 206 is formed on a predetermined region of the p-type contact layer 205 using the electron beam evaporation technique. Note that, in the third embodiment, when forming the p-side ohmic electrode 206, the Si layer 206a (refer to FIG. 32) having a thickness of about 1 nm, the Pd layer 206b having a thickness of about 5 nm, and the Ti layer 206c having a thickness of about 1 nm, are formed in sequence. At this time, since the Si layer 206a is formed using the electron beam evaporation technique, the Si layer 206a is formed as amorphous silicon Furthermore, using the plasma CVD technique, a surface protective film 207 configured of SiO₂, which has a thickness of about 300 nm, is formed to cover the entire surface. Thereafter, using the photolithographic technique, a resistor 213 is formed on a predetermined region of the surface protective film 207.

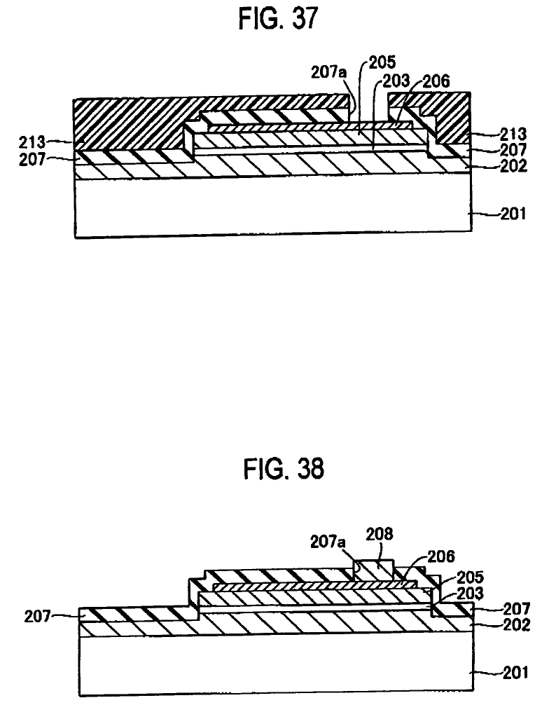

Next, as shown in FIG. 37, with the resistor 213 disposed as a mask, the surface protective film 207 is etched using the buffered HF. Thereby, an opening 207a is formed on the surface protective film 207. Thereafter, the resistor 213 is removed.

Subsequently, as shown in FIG. 38, on a surface of the p-side ohmic electrode 206 exposed through the opening 207a, a Ti layer (not shown) having a thickness of about 10 nm, a Pd layer (not shown) having a thickness of about 100 nm, and an Au layer (not shown) having a thickness of about 300 nm are deposited in sequence from the side of the p-side ohmic electrode 206. Thereby, the pad electrode 208 is formed, by use of the electron beam evaporation technique.

Thereafter, as shown in FIG. 31, using the same process of forming the opening 207a on the surface protective film 207, an opening 207b is formed on a predetermined region of the surface protective film 207 on the n-type clad layer 202. Subsequently, on a surface of the n-type clad layer 202 exposed through the opening 207b, the Si layer 209a (refer to FIG. 33) having a thickness of about 1 nm, the Al layer 209b (refer to FIG. 33) having a thickness of about 6 nm, and the Pd layer 209c (refer to FIG. 33) having a thickness of about 100 nm, are deposited in sequence from the side of the n-type clad layer 202. Thereby, the n-side ohmic electrode 209 is formed, by use of the electron beam evaporation technique. At this time, since the Si layer 209a is formed using the electron beam evaporation technique, the Si layer 209a is formed as amorphous silicon. Thereafter, using the electron beam evaporation technique, the pad electrode 210, which is formed of an Au layer having a thickness of about 300 nm, is formed on the n-side ohmic electrode 209.

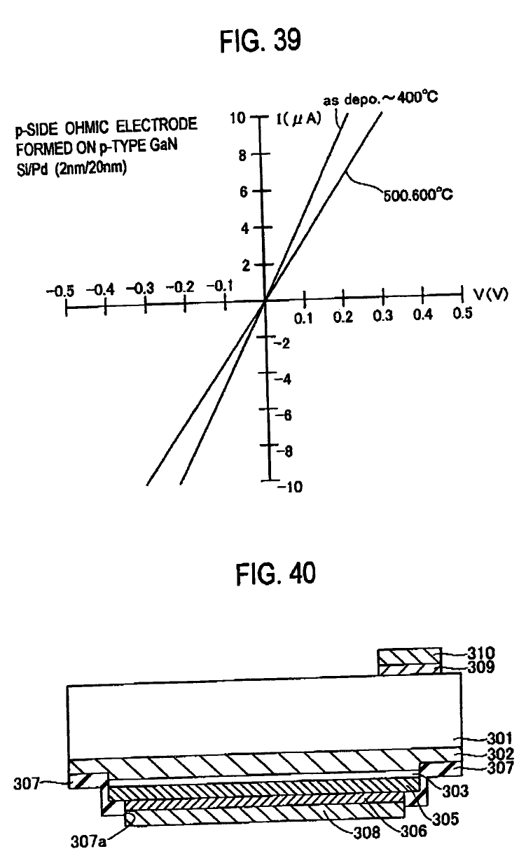

FIG. 39 is a view for describing an experiment conducted for validating an effect of the p-side ohmic electrode of the nitride semiconductor light-emitting diode device of the third embodiment shown in FIG. 31. Next, with reference to FIGS. 9 and 39, a description will be given for the experiment, which is conducted for validating an effect of the p-side ohmic electrode of the nitride semiconductor light-emitting diode device of the aforementioned third embodiment. In this experiment, as in the first embodiment, a sample (refer to FIG. 9) for measuring the respective ohmic characteristics of a p-side ohmic electrode, and of an n-side ohmic electrode, is evaluated. For this sample, as shown in FIG. 9, the p-type GaN layer 22a having a thickness of about 3 nm is formed on the n-type GaN substrate 21. Then, using the vacuum evaporation method, two pieces of the p-side ohmic electrodes 23 are formed on the p-type GaN layer 22a with a predetermined interval. Thereafter, using the vacuum evaporation method, two pieces of the n-side ohmic electrodes 24 are formed on a lower surface of the n-type GaN substrate 21 with a predetermined interval. Incidentally, the p-side ohmic electrode 23 is formed in such a way that a Si layer having a thickness of about 2 nm is provided, and that a Pd layer having a thickness of about 20 nm is formed on the Si layer. Current-voltage characteristics are measured by conducting the same experiment as that for validating the effect of the p-side ohmic electrode of the aforementioned first embodiment. The results thereof are shown in FIG. 39.

It has been revealed that, in the case of the third embodiment where the p-side ohmic electrode 23 is formed on the p-type GaN layer 22a, the ohmic characteristics of the p-side ohmic electrode 23 are not deteriorates More specifically, when performing heat treatment at a temperature not greater than 400° C., the ohmic characteristics of the p-side ohmic electrode 23 are the same as those where heat treatment is not performed (as depo.), and are not deteriorated. When performing heat treatment at temperatures of about 500° C. and about 600° C., resistance somewhat increases, and the ohmic characteristics of the p-side ohmic electrode 23 are somewhat deteriorated.

### Fourth Embodiment

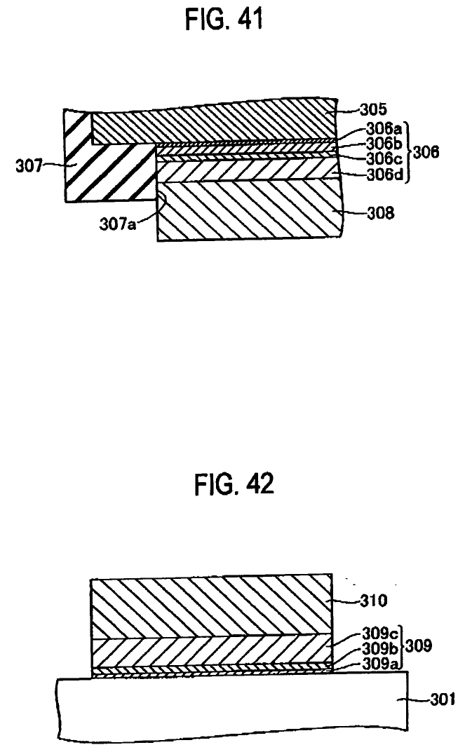

FIG. 40 is a sectional view showing a structure of a nitride semiconductor light-emitting diode device (a nitride semiconductor device) of a fourth embodiment of the present invention FIGS. 41 and 42 are views for describing in detail the structure of the nitride semiconductor light-emitting diode device of the fourth embodiment shown in FIG. 40. In this fourth embodiment, with reference to FIGS. 40 to 42, a description will be given for a case where, unlike the third embodiment, a p-side ohmic electrode is configured of a Si layer, a Pt layer, a Ti layer, and a Pd layer.

In the nitride semiconductor laser device of the fourth embodiment, as shown in FIG. 40, an n-type dad layer 302 configured of GaN is formed on a lower surface of an n-type GaN substrate 301. The n-type clad layer 302 includes a convex portion of about 400 nm in thickness and a flat portion. Incidentally, the n-type GaN substrate 301 is one example of the “n-type nitride semiconductor device” of the present invention. An active layer 303 of the MQW structure is formed on a predetermined region of the convex portion of the n-type clad layer 302. In the MQW structure for the active layer 303, the layers of the same configuration and thickness as those of the active layer 3 of the first embodiment are deposited. Furthermore, a p-type contact (clad) layer 305 of about 400 nm in thickness configured of GaN doped with Mg, is formed on a lower surface of the active layer 303. Incidentally, the p-type contact layer 305 is one example of the “p-type nitride semiconductor device” of the present invention. A predetermined region halfway into the n-type clad layer 302 from a lower surface of the p-type contact layer 305 is removed.

A surface protective film 307 configured of SiO₂ is formed to cover each of the sides of lower surfaces of the p-type contact layer 305 and of the n-type clad layer 302 This surface protective film 307 has an opening 307a on a portion in a predetermined region of a lower surface of the p-type contact layer 305. Moreover, on the p-type contact layer 305, a p-side ohmic electrode 306 is formed through the opening 307a so that the p-side ohmic electrode 306 is in contact with the p-type contact layer 305. Incidentally, the p-side ohmic electrode 306 is one example of the “ohmic electrode” of the present invention.

In the fourth embodiment, as shown in FIG. 41, the p-side ohmic electrode 306 is configured of a Si (silicon) layer 306a configured of amorphous silicon of about 2 nm in thickness which contacts with a lower surface of the p-type contact layer 305; a Pt layer 306b having a thickness of about 29 nm; a Ti layer 306c having a thickness of about 10 nm; and a Pd layer 306d having a thickness of about 100 nm. The Si layer 306a, the Pt layer 306b, the Ti layer 306c, and the Pd layer 306d are disposed in the above sequence from the side of the p-type contact layer 305. Incidentally, the Pt layer 306b, the Ti layer 306c, and the Pd layer 306d are examples of the “first metal layer” of the present invention. Furthermore, a pad electrode 308, which is formed of an Au layer having a thickness of about 300 nm, is formed on a lower surface of the p-side ohmic electrode 306 so as for the pad electrode 308 to be contacted therewith Incidentally, the pad electrode 308 is one example of the “second metal layer” of the present invention.

On a predetermined region of the n-type GaN substrate 1, an n-side ohmic electrode 309 is formed as shown in FIG. 40 Incidentally, the n-side ohmic electrode 309 is one example of the “ohmic electrode” of the present invention. As shown in FIG. 42, the n-side ohmic electrode 309 includes a Si layer 309a configured of amorphous silicon having a thickness of about 1 nm which contacts with a surface of the n-type GaN substrate 301; an Al layer 309b having a thickness of about 10 nm; and a Pd layer 309c having a thickness of about 100 nm. The Si layer 309a, Al layer 309b, and Pd layer 309c are disposed in the above sequence from the side of the n-type GaN substrate 301. Incidentally, the Al layer 309b and the Pd layer 309c are examples of the “first metal layer” of the present invention. In addition, as shown in FIG. 40, a pad electrode 310, which is formed of an Au layer having a thickness of about 300 nm, is formed on the n-side ohmic electrode 309. Incidentally, the pad electrode 310 is one example of the “second metal layer” of the present invention.

Next, a description will be given for results of measurement of forward voltages at a time when a forward current of 20 mA flows in the nitride semiconductor laser device of the fourth embodiment. In the nitride semiconductor laser device of the fourth embodiment, as in the case of the third embodiment, a forward voltage after the assembling process remains unchanged, as compared with that after wafer process. From these results, it has been confirmed that, even in a case where, unlike the third embodiment, the p-side ohmic electrode is configured to include the Si layer, the Pt layer, and the Pd layer, deterioration of the ohmic characteristics between the p-side ohmic electrode 306 and the p-type contact layer 305, and is between the n-side ohmic electrode 309 and the n-type GaN substrate 301, can be suppressed as in the third embodiment, the deterioration being caused by the heat of about 250° C. to about 350° C. applied during soldering in the assembling of the p-side ohmic electrode 306, and of the n-side ohmic electrode 309 after the forming of the same. Incidentally, optical reflectance rate of the p-side ohmic electrode 306 is approximately 70% with emission wavelength of 400 nm, and is roughly the same as that of a conventional p-side ohmic electrode.

As described above, in the fourth embodiment, the p-side ohmic electrode 306 is cored to include the Si layer 306a of about 2 nm in thickness which contacts with a lower surface of the p-type contact layer 305; the Pt layer 306b of about 29 nm in thickness formed on a lower surface of the Si layer 306a; the Ti layer 306c of about 10 nm in thickness formed on a lower surface of the Pt layer 306b; and the Pd layer 306d of about 100 nm in thickness formed on a lower surface of the Ti layer 306c. The n-side ohmic electrode 309 is configured to include the Si layer 309a of about 1 nm in thickness which contacts with a surface of the n-type GaN substrate 301; the Al layer 309b of about 10 nm in thickness formed on the Si layer 309a; and the Pd layer 309c of about 100 nm in thickness formed on the Al layer 309b. Hence, as in the first embodiment, even when the heat of about 250° C. to about 350° C. is applied during soldering in the assembling of the p-side ohmic electrode 306, and of the n-side ohmic electrode 309 after the forming of the same, ohmic characteristics are not deteriorated easily, due to the effects of the Si layers 306a and 309a, which contact respectively with the main surfaces of the p-type contact layer 305 and the n-type GaN substrate 301. Thus, deterioration, due to heat, of the ohmic characteristics between the p-side ohmic electrode 306 and the p-type contact layer 305, and between the n-side ohmic electrode 309 and the n-type GaN substrate 301, can be suppressed This point has been validated by an experiment to be described later.

Incidentally, other effects of the fourth embodiment are the same as those in the first embodiment.

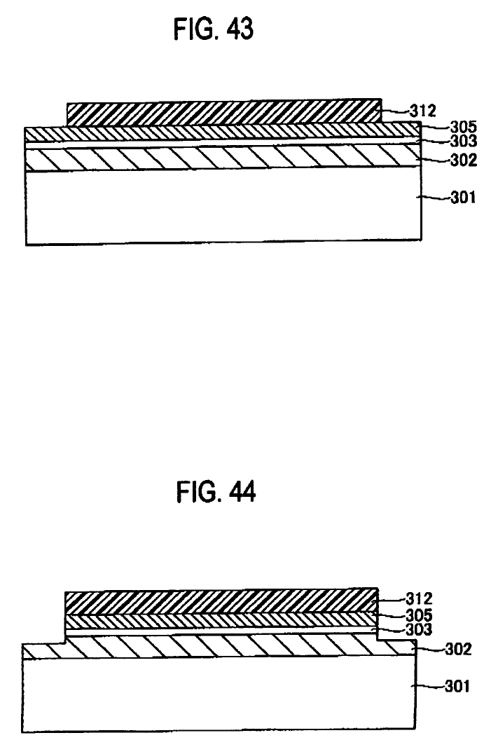

FIGS. 43 to 46 are sectional views for describing a process of manufacturing the nitride semiconductor light-emitting diode device of the fourth embodiment shown in FIG. 40. Next, referring to FIGS. 40 to 46, the process of manufacturing the nitride semiconductor light-emitting diode device of the fourth embodiment is described. Note that, when manufacturing a nitride semiconductor light-emitting diode device, the respective layers are formed on an n-type substrate. In the fourth embodiment, therefore, the description will be given with reference to the drawings (FIGS. 43 to 46), the states of which correspond to the state of drawing of FIG. 40 rotated 180 degrees to be turned upside down.

First, as shown in FIG. 43, using the MOCVD technique, the n-type clad layer 302 configured of GaN having a thickness of about 400 nm, the active layer 303 of the MQW structure, and the p-type contact (clad) layer 305 configured of GaN doped with Mg having a thickness of about 400 nm, are developed in sequence on a lower surface of the n-type GaN substrate 301. Note that the active layer 303 is formed in the same way as that for the active layer 3 of the first embodiment. Then, using the photolithographic technique, a resistor 312 is formed on a predetermined region of the p-type contact layer 305.

Subsequently, as shown in FIG. 44, with the resistor 312 disposed as a mask, a predetermined region halfway into the n-type clad layer 302 from a lower surface of the p-type contact layer 305 is removed using the RIE technique. Thereby, a portion of the n-type clad layer 302 is exposed Thereafter, the resistor 312 is removed.

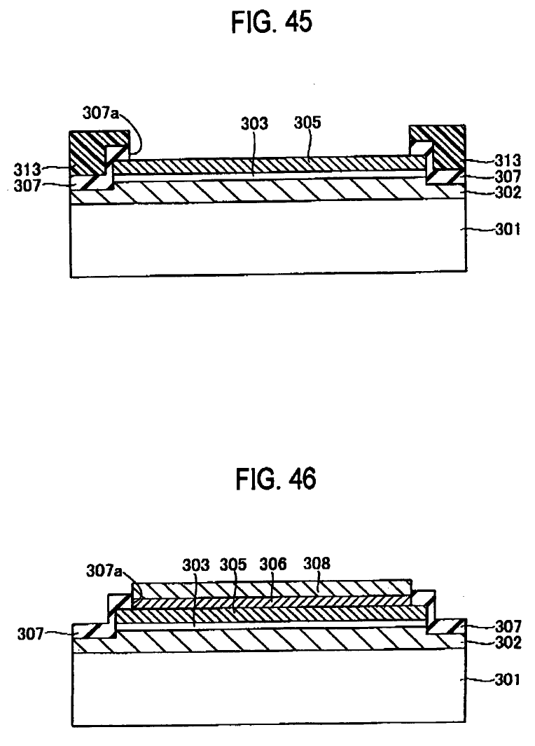

Next, as shown in FIG. 45, using the plasma CVD technique, a surface protective film 307, which is configured of SiO₂, and which has a thickness of about 300 nm, is formed to cover the entire surface. Thereafter, using the photolithographic technique, a resistor 313 is formed on a predetermined region of the surface protective film 307. Then, with the resistor 13 disposed as a mask, the surface protective film 307 is etched using the buffered HF. Thereby, an opening 307a is formed on the surface protective film 307. Thereafter, the resistor 313 is removed.

Then, as shown in FIG. 46, using the electron beam evaporation technique, the ohmic electrode 306 is formed on a surface of the p-type contact layer 305 exposed through the opening 307a. Note that, in the fourth embodiment, when forming the p-type ohmic electrode 306, the Si layer 306a (refer to FIG. 41) having a thickness of about 2 nm, the Pt layer 306b having a thickness of about 20 nm, the Ti layer 306c having a thickness of about 10 nm, and the Pd layer 306d having a thickness of about 100 nm, are formed in sequence. At this time, since the Si layer 306a is formed using the electron beam evaporation technique, the Si layer 306a is formed as amorphous silicon. Then, using the electron beam evaporation technique, an Au layer having a thickness of about 300 mm is deposited on the p-side ohmic electrode 306. Thereby, a pad electrode 308 is formed

Thereafter, as shown in FIG. 40, using the electron beam evaporation technique, a Si layer 309a (refer to FIG. 42) having a thickness of about 1 nm, an Al layer 309b having a thickness of about 10 nm, and a Pd layer 309c having a thickness of about 100 nm are deposited in sequence from the side of the n-type GaN substrate 301, on a predetermined region of the n-type GaN substrate 301. Thereby, an n-side ohmic electrode 309 is formed At this time, since the Si layer 309a is formed using the electron beam evaporation technique, the Si layer 309a is formed as amorphous silicon. Then, using the electron beam evaporation technique, a pad electrode 310, which is formed of an Au layer having a thickness of about 300 nm, is formed on the n-side ohmic electrode 309.

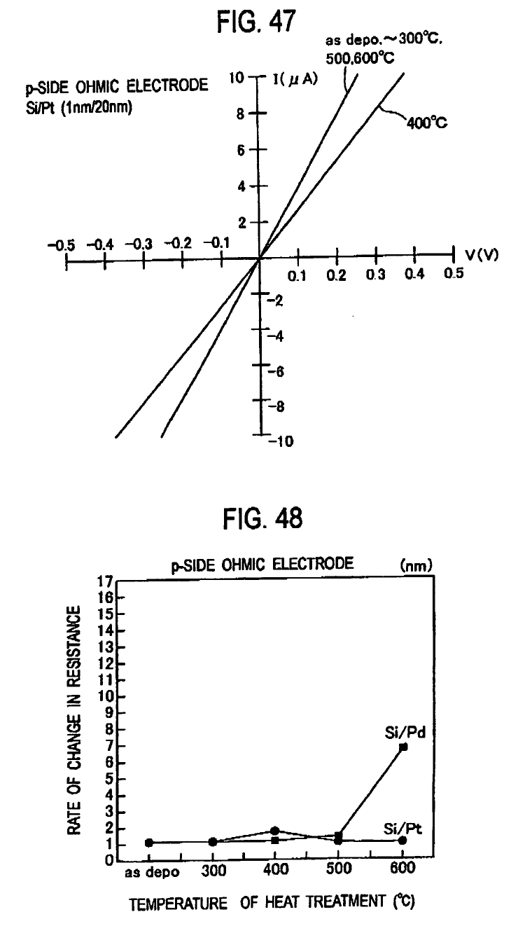

FIGS. 47 and 48 are views for describing an experiment conducted for validating an effect of the p-side ohmic electrode of the nitride semiconductor light-emitting diode device of the fourth embodiment shown in FIG. 40. Next, with reference to FIGS. 9, 47, and 48, a description will be given for the experiment, which is conducted for validating an effect of the p-side ohmic electrode of the nitride semiconductor light-emitting diode device of the fourth embodiment. In this experiment, as in the first embodiment, a sample (refer to FIG. 9) for measuring the respective ohmic characteristics of the p-side ohmic electrode and of the n-side ohmic electrode is evaluated. Moreover, the p-side ohmic electrode 23 (refer to FIG. 9) is configured to include a Si layer having a thickness of about 1 nm, and a Pt layer having thickness of about 20 nm on the Si layer. Then, by conducting the same experiment as that for validating the effect of the p-side ohmic electrode of the aforementioned first embodiment, current-voltage characteristics are measured, and thereafter, rates of change in resistance are calculated. Results of measurement of the current-voltage characteristics are shown in FIG. 47, and results of calculation of the rates of change in resistance are shown in FIG. 48.

It has been revealed that, in the case of the fourth embodiment where the p-side ohmic electrode 23 is formed with the Si layer and the Pt layer, as shown in FIGS. 47 and 48, deterioration of the ohmic characteristics of the p-side ohmic electrode 23 by heat treatment is suppressed. In addition, it has also been revealed that, in the case where the p-side ohmic electrode 23 is formed with the Si layer and the Pt layer, as shown in FIG. 48, the ohmic characteristics as favorable as the ones for the nitride semiconductor light-emitting diode device of the first embodiment, in which the p-ride ohmic electrode 23 is formed with the Si layer and the Pd layer, can be obtained. More specifically, in the case where the p-side ohmic electrode 23 is formed with the Si layer and the Pt layer, as shown in FIG. 47, when performing heat treatment at a temperature of about 300° C., the ohmic characteristics of the p-side ohmic electrode 23 are the same as those where heat treatment is not performed (as depo.), and are not deteriorated. When performing heat treatment at a temperature of about 400° C., resistance somewhat increases, and the ohmic characteristics of the p-side ohmic electrode 23 are somewhat deteriorated. Furthermore, when performing heat treatment at temperatures of about 500° C. and about 600° C., the ohmic characteristics, which are the same as those after making the sample (the case where heat treatment is not performed), are obtained.

### Fifth Embodiment

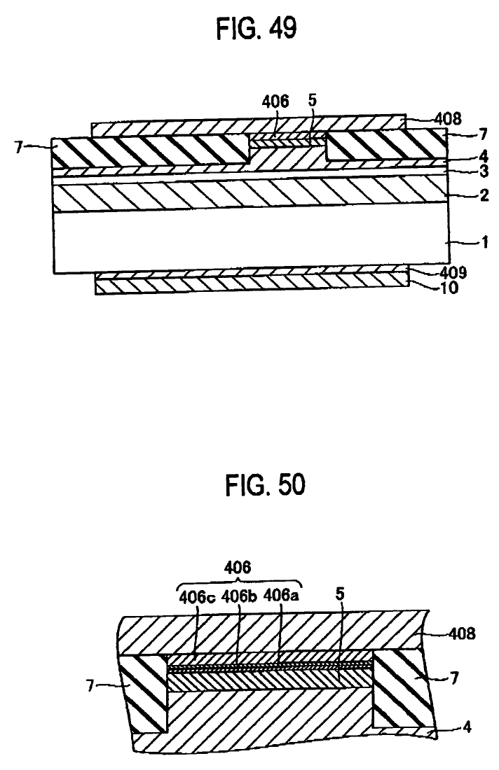

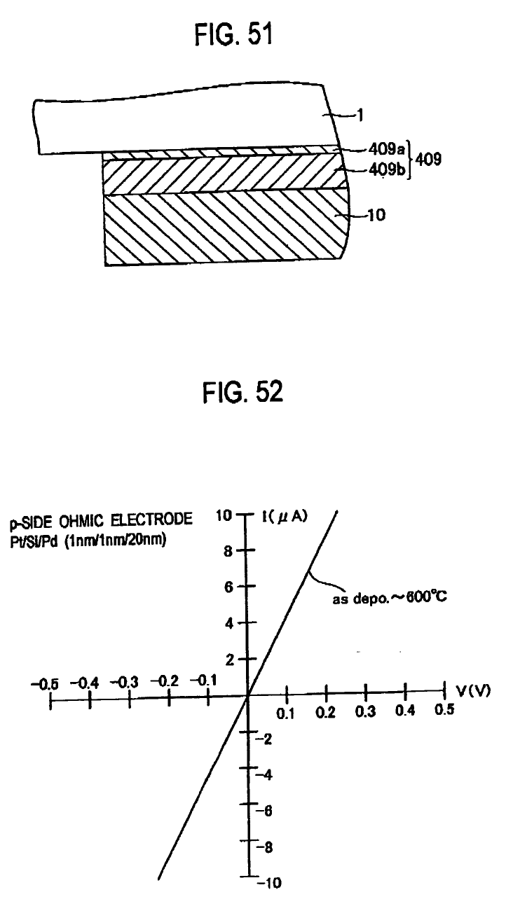

FIG. 49 is a sectional view showing a structure of a nitride semiconductor laser device (a nitride semiconductor device) of a fifth embodiment. FIGS. 50 and 51 are views for describing in detail the structure of the nitride semiconductor laser device of the fifth embodiment shown in FIG. 49. In this fifth embodiment, referring to FIGS. 49 to 51, a description will be given for a case where, unlike the first embodiment, a Si layer is included in a p-side ohmic electrode only, and a Pt layer or a Pd layer is further provided between the Si layer and a p-side contact layer.

In the nitride semiconductor laser device of the fifth embodiment, as shown in FIG. 49, an n-type GaN substrate 1, an n-type clad layer 2, an active layer 3, a p-type clad layer 4, and a p-type contact layer 5, each having the same configuration and thickness as those of the first embodiment, are formed. Furthermore, on the p-type contact layer 5, a p-side ohmic electrode 406 is formed. Incidentally, the p-side ohmic electrode 406 is one example of the “ohmic electrode” of the present invention.

In this event, in the fifth embodiment, as shown in FIG. 50, the p-ride ohmic electrode 406 is configured of a Pt (Pd) layer 406a of about 1 nm in thickness which forms an ohmic contact with the p-type contact layer 5; a Si (silicon) layer 406b configured of amorphous silicon having a thickness of about 1 nm; and a Pd layer 406c of about 20 nm in thickness formed on an upper surface of the Si layer 406b. Incidentally, the reason why the Pt (Pd) layer 406a is formed in an insular shape (not shown) may be because the Pt (Pd) layer 406a has a small thickness of about 1 nm. Accordingly, it may be inferred that the Si layer 406b partially contacts with a portion of the p-type contact layer 5, where the Pt (Pd) layer 406a is not formed. Incidentally, the Pt (Pd) layer 406a is one example of the “ohmic metal layer” of the present invention, and the Pd layer 406c is one example of the “first metal layer” of the present invention.

Furthermore, as shown in FIG. 49, as in the first embodiment, a current block layer 7 having the same configuration and thickness of those of the first embodiment is formed to cover sides of a convex portion and an upper surface of flat portions of the p-type clad layer 4. Moreover, a pad electrode 408 is formed on the respective predetermined portions of the p-side ohmic electrode 406 and of the current block layer 7 so that the pad electrode 408 contacts with an upper surface of the p-side ohmic electrode 406. Incidentally, the pad electrode 408 is one example of a “second metal layer” of the present invention. This pad electrode 408 is configured of a Ti layer (not shown) having a thickness of about 100 nm, a Pd layer (not shown) having a thickness of about 200 nm, and an Au layer (not shown) having a thickness of about 300 nm. The Ti layer, the Pd layer, and the Au layer are disposed in the above sequence from the side of the p-side ohmic electrode 406.

In addition, an n-type ohmic electrode 409 is formed on a predetermined region of a lower surface of the n-type GaN substrate 1. Moreover, in the fifth embodiment, as shown in FIG. 51, the n-type ohmic electrode 409 is configured of an Al layer 409a having a thickness of about 6 nm, and a Pd layer 409b having a thickness of about 100 nm. The Al layer 409a and the Pd layer 409b are disposed in the above sequence from the side of the n-type GaN substrate 1. In addition, as shown in FIG. 49, a pad electrode 10, which has the same configuration and thickness as those of the aforementioned first embodiment, is formed on a lower surface of the n-type ohmic electrode 409.

Next, a description will be given for results of measurement of forward voltages at a time when a forward current of about 20 mA flows in the nitride semiconductor laser device of the fifth embodiment. Note that, as a comparative example, forward voltages are measured also for a conventional nitride semiconductor laser device, in which the p-side ohmic electrode is provided with a Pd layer only and not with a Si layer, and in which the n-side ohmic electrode is provided with an Al layer and a Pd layer and not with a Si layer. As a result, in the nitride semiconductor laser a device of the fifth embodiment, a forward voltage is 4.4 V after the wafer process, and is 4.8 V after the assembling process. In contrast, in the conventional nitride semiconductor laser device, a forward voltage is 4.5 V after the wafer process, and is 7.5 V after the assembling process. In other words, in the conventional nitride semiconductor laser device, the forward voltage after the assembling process is increased by 3.0 V. On the other hand, in the nitride semiconductor laser device of the fifth embodiment, the forward voltage after the assembling process is increased by 0.4 V. A reason for the above results can be considered as follows. In the nitride semiconductor laser device of the fifth embodiment, since the n-type ohmic electrode 409 has a conventional structure, the forward voltage after the assembling process is increased by 0.4 V. On the other hand, the Si layer 406b is provided to the p-side ohmic electrode 406. Thereby, deterioration of the ohmic characteristics after the assembling process can be suppressed. It has also been revealed that, when the Pt (Pd) layer 406a having a thickness of about 1 nm is provided between the p-type contact layer 5 and the Si layer 406b of the p-side ohmic electrode 406, it is possible to cause the p-side ohmic electrode 406 to form a favorable contact with the p-type contact layer 5.

As described above, in the fifth embodiment, the p-side ohmic electrode 406 is configured to include the Pt (Pd) layer 406a having a thickness of about 1 nm formed on the p-type contact layer 5; the Si layer 406b having a thickness of about 1 nm formed on the Pt (Pd) layer 406a; and the Pd layer 406c having a thickness of about 20 nm formed on the Si layer 406b. As in the first embodiment, therefore, even when the heat of about 250° C. to about 350° C. is applied during soldering in the assembling of the p-side ohmic electrode 406 after the forming of the same, the ohmic characteristics are not deteriorated easily, due to the effect of the Si layer 406b formed on the p-type contact layer 5. Accordingly, deterioration, due to heat, of the ohmic characteristics between the p-side ohmic electrode 406 and the p-type contact layer 5, can be suppressed This point has been validated by an experiment to be described later. The following points can be considered as effects of the Si layer 406b. That is, as in the first embodiment, unlike the case where the Pd layer 406c is formed directly on a main surface of the p-type contact layer 5 having a large band-gap (band-gap: about 3.5 eV), the Pd layer 406c is formed through the Si layer 406b, which has a small band-gap (band-gap: about 1.1 eV), and which is interposed between the Pd layer 406c and the p-type contact layer 5. Thereby, it is considered to be made possible to cause the p-side ohmic electrode 406 to form a more favorable ohmic contact with the p-type contact layer 5, and to maintain the favorable ohmic contact even when the heat of about 250° C. to about 350° C. is applied during soldering at the time of assembly.

Furthermore, in the fifth embodiment, the Pt (Pd) layer 406a having a thickness of about 1 nm which forms an ohmic contact with the p-type contact layer 5, is provided between the p-type contact layer 5 and the Si layer 406b. As mentioned above, even in the case where the Si layer 406b is formed on the p-type contact layer 5 with the Pt (Pd) layer 406a, and where the Pd layer 406c is formed on the Si layer 406b, it is possible to cause the p-side ohmic electrode 406, which includes the Pt (Pd) layer 406a, the Si layer 406b, and the Pd layer 406c, to form a favorable ohmic contact with the p-type contact layer 5 due to the effect of the Si layer 406b. In addition, the above favorable ohmic contact can be maintained even when the heat of about 250° C. to about 350° C. is applied in the assembling process.

Incidentally, other effects of the fifth embodiments are the same as those of the first embodiment.

Next, referring to FIGS. 49 to 51, a process of manufacturing the nitride semiconductor laser device of the fifth embodiment is described.

First, using the same process as that of the first embodiment, the n-type clad layer 2, the active layer 3, the p-type clad layer 4, and the p-type contact layer 5 are developed in sequence on the n-type GaN substrate 1. Thereafter, as shown in FIG. 49, using the electron beam evaporation technique, the p-side ohmic electrode 406 is formed on the p-type contact layer 5.

In the fifth embodiment, when forming the p-side ohmic electrode 406, the Pt (Pd) layer 406a (refer to FIG. 50) having a thickness of about 1 nm, the Si layer 406b having a thickness of about 1 nm, and the Pd layer 406c having a thickness of about 20 nm, are formed in sequence. At this time, the Pt (Pd) layer 406a is formed resulting in a small thickness of about 1 nm, and this may be the reason why the Pt (Pd) layer 406a is formed in an insular shape (not shown). Accordingly, it may be inferred that the Si layer 406b partially contacts with a portion of the p-type contact layer 5 where the Pt (Pd) 406a is not formed. Moreover, since the Si layer 406b is formed using the electron beam evaporation technique, the Si layer 406b is formed as amorphous silicon. As shown in FIG. 49, the current block layer 7 is formed in the same way as that of the first embodiment.

Subsequently, using the electron beam evaporation technique, on an upper surface of the p-side ohmic electrode 406 and on a predetermined region of the current block layer 7, a Ti layer (lot shown) having a thickness of about 100 nm, a Pd layer (not shown) having a thickness of about 200 nm, and an Au layer (not shown) having a thickness of about 300 nm, are deposited in sequence from the side of the pride ohmic electrode 406. Thereby, the pad electrode 408 is formed. Then, the n-type GaN substrate 1 is formed to have a thickness of about 100 nm by means of polishing and etching. Thereafter, using the electron beam evaporation technique, the Al layer 409a (refer to FIG. 51) having a thickness of about 6 nm and the Pd layer 409b having a thickness of about 100 nm are deposited in sequence from the side of the n-type GaN substrate 1, on a predetermined region of a lower surface (a reverse surface) of the n-type GaN substrate 1. Thereby, the n-side ohmic electrode 409 is formed thereon. Then, the pad electrode 10 is formed on a lower surface of the n-side ohmic electrode 409 as in the first embodiment.

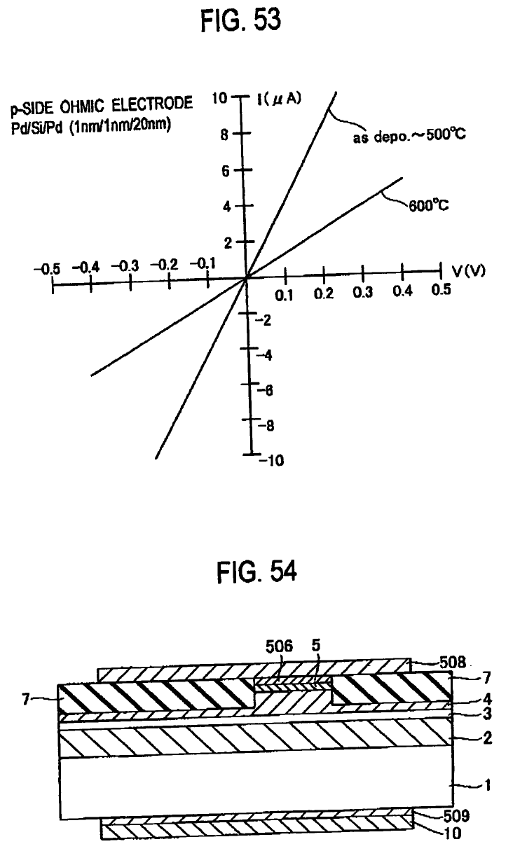

FIGS. 52 and 53 are views for describing an experiment conducted for validating an effect of the p-side ohmic electrode of the nitride semiconductor laser device of the fifth embodiment. Referring to FIGS. 9, 52, and 53, a description will be given for the experiment conducted for validating an effect of the p-side ohmic electrode of the nitride semiconductor laser device of the aforementioned fifth embodiment. In this experiment, as in the first embodiment, samples (refer to FIG. 9) for measuring the ohmic characteristics of the p-side ohmic electrode are evaluated. One sample is made such that the p-ride ohmic electrode 23 (refer to FIG. 9) is configured of a Pt layer having a thickness of about 1 nm, a Si layer having a thickness of about 1 nm formed on the Pt layer, and a Pd layer having a thickness of about 20 nm formed on the Si layer. Another sample is made such that the p-side ohmic electrode 23 is configured of a Pd layer having a thickness of about 1 nm, a Si layer having a thickness of about 1 nm formed on the Pd layer, and a Pd layer having a thickness of about 20 nm formed on the Si layer. Then, current-voltage characteristics are measured by conducting the same experiment as that for validating the effect of the p-side ohmic electrode of the first embodiment.

In the case of the fifth embodiment where the p-side ohmic electrode 23 is formed of the Pt layer, the Si layer, and the Pd layer, it has been revealed that, when performing heat treatment at a temperature not greater than about 600° C., the ohmic characteristics of the p-side ohmic electrode 23 is not deteriorated. Moreover, in the case of the fifth embodiment where the p-side ohmic electrode 23 is formed of the Pd layer, the Si layer, and the Pd layer, it has also been revealed that, when performing heat treatment at a temperature not greater than about 500° C., the ohmic characteristics of the p-side ohmic electrode 23 are not deteriorated. More specifically, in the case where the p-side ohmic electrode 23 is formed of the Pt layer, the Si layer, and the Pd layer, as shown in FIG. 52, when performing heat treatment at a temperature of about 300° C. to about 600° C., the ohmic is characteristics of the p-side ohmic electrode 23 is the same as those where heat treatment is not performed (as depo.), and are not deteriorated. In the case where the p-side ohmic electrode 23 is formed of the Pd layer, the Si layer, and the Pd layer, as shown in FIG. 53, when performing heat treatment at a temperature of about 300° C. to about 500° C., the ohmic characteristics of the p-side ohmic electrode 23 is the same as those where heat treatment is not performed (as depo.), and are not deteriorated. When performing heat treatment at a temperature of about 600° C., resistance increases, and the ohmic characteristics of the p-side ohmic electrode 23 are deteriorated. From these results, it has been revealed that, even in the case where the Si layer, of which the p-side ohmic electrode 23 is configured, is not in contact with the p-type contact layer (p-type InGaN layer 22), and where the Pd layer or the Pt layer is formed between the Si layer and the p-type contact layer, it is possible to cause the p-side ohmic electrode 23 and the p-type contact layer (p-type InGaN layer 22) to form a favorable ohmic contact with each other due to the effect of the Si layer. In addition, it has been confirmed that the favorable ohmic contact can be maintained even when the heat of about 250° C. to about 350° C. is applied in the assembling process.

### Sixth Embodiment

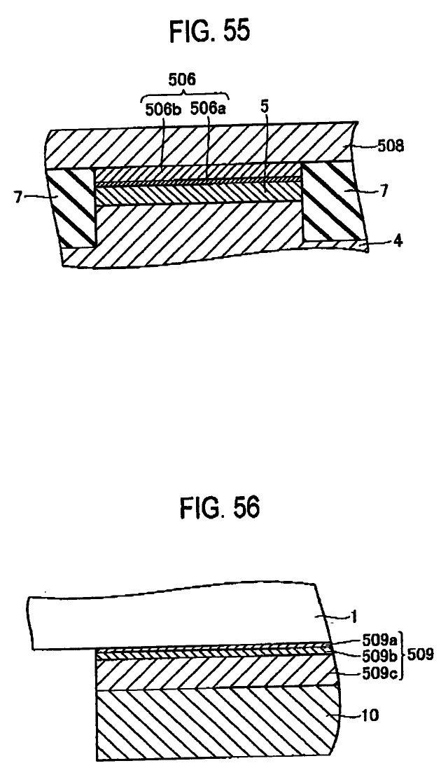

FIG. 54 is a sectional view showing a structure of a nitride semiconductor laser device (a nitride semiconductor device) of a sixth embodiment of the present invention. FIGS. 55 and 56 are views for describing in detail the structure of the nitride semiconductor laser device of the sixth embodiment shown in FIG. 54. In this sixth embodiment, referring to FIGS. 54 to 56, a description will be given for a case where, unlike the aforementioned first embodiment, a Si layer is included in an n-side ohmic electrode only.

In the nitride semiconductor laser device of the sixth embodiment, as shown in FIG. 54, an n-type GaN substrate 1, an n-type clad layer 2, an active layer 3, a p-type clad layer 4, and a p-type contact layer 5, each having the same configuration and thickness as those of the first embodiment, are formed. Furthermore, a p-side ohmic electrode 506 is formed on the p-type contact layer 5.

In this event, in the sixth embodiment, as shown in FIG. 55, the p-side ohmic electrode 506 is configured of a Pt layer 506a having a thickness of about 1 nm, and a Pd layer 506b having a thickness of about 20 nm. The Pt layer 506a and the Pd layer 506b are disposed in the above sequence from the side of the p-type contact layer 5.

As shown in FIG. 54, as in the first embodiment, a current block layer 7, which has the same configuration and thickness of the first embodiment, is formed such that the current block layer 7 covers sides of a convex portion, and an upper surface of flat portions, of the p-type clad layer 4. Moreover, a pad electrode 508 is formed on a predetermined region of the p-side ohmic electrode 506, and of the current block layer 7 so that the pad electrode 508 contacts with an upper surface of the p-side ohmic electrode 506. This pad electrode 608 is configured of a Ti layer (not shown) having a thickness of about 100 nm, a Pd layer (not shown) having a thickness of about 200 nm, and an Au layer (not shown) having a thickness of about 300 nm. The Ti layer, the Pd layer, and the Au layer are disposed in the above sequence from the side of the p-side ohmic electrode 506.

Furthermore, an n-type ohmic electrode 509 is formed on a predetermined region on a lower surface of the n-type GaN substrate 1. Incidentally, the n-type ohmic electrode 509 is one example of the “ohmic electrode” of the present invention. Note that, in the sixth embodiment, as shown in FIG. 56, the n-type ohmic electrode 509 is configured of a Si (silicon) layer 509a configured of amorphous silicon having a thickness of about 1 nm which contacts with a surface of the n-type GaN substrate 1; an Al layer 509b having a thickness of about 6 nm; and a Pd layer 509c having a thickness of about 30 nm. The Si layer 509a, the Al layer 509b, and the Pd layer 509c are disposed in the above sequence from the side of the n-type GaN substrate 1. Incidentally, the Al layer 509b and the Pd layer 509c are examples of the “first metal layer” of the present invention. In addition, as shown in FIG. 54, the pad electrode 10 having the same configuration and thickness of the aforementioned first embodiment is formed on a lower surface of the n-type ohmic electrode 509.

Next, a description will be given for results of measurement of forward voltages at a time when a forward current of about 20 mA flows in the nitride semiconductor laser device of the sixth embodiment. Note that, as a comparative example, as in the fifth embodiment, forward voltages are measured also for a conventional nitride semiconductor laser device, in which the p-ride ohmic electrode is provided with a Pd layer only and not with a Si layer, and in which the n-side ohmic electrode is provided with Al and Pd layers and not with a Si layer. As a result, in the nitride semiconductor laser device of the sixth embodiment, a forward voltage is 4.4 V after the wafer process, and is 7.0 V after the assembling process. In contrast, in the conventional nitride semiconductor laser device, a forward voltage is 4.5 V after the wafer process, and is 7.5 V after the assembling process. In other words, in the conventional nitride semiconductor laser device, the forward voltage after the assembling process is increased by 3.0 V. On the other hand, in the nitride semiconductor laser device of the sixth embodiment, the forward voltage after the assembling process is increased by 2.6 V. A reason for the above results can be considered as follows. In the nitride semiconductor laser device of the sixth embodiment, since the p-side ohmic electrode 506 has a conventional structure, the forward voltage after the assembling process is increased by 2.6 V. On the other hand, the Si layer 509a is provided to the n-side ohmic electrode 509 whereby deterioration of the ohmic characteristics after the assembling process can be suppressed.

As described above, in the sixth embodiment, the n-type ohmic electrode 509 is configured of the Si layer 509a having a thickness of about 1 nm which contacts with a lower surface of the n-type GaN substrate 1; the Al layer 509b having a thickness of about 6 nm formed on a lower surface of the Si layer 509a; and the Pd layer 509c having a thickness of about 30 n, formed on a lower surface of the Al layer 509b. Accordingly, as in the first embodiment, even when the heat of about 250° C. to about 350° C. is applied during soldering in the assembling of the n-side ohmic electrode 509 after the forming of the same, ohmic characteristics are not deteriorated easily, due to the effect of the Si layer 509a contacting with a main surface of the n-type GaN substrate 1. Hence, deterioration, due to heat, of the ohmic characteristics between the n-side ohmic electrode 509 and the n-type GaN substrate 1 can be suppressed.

Incidentally, other effects of the sixth embodiments are the same as those of the first embodiment.

Next, referring to FIGS. 54 to 56, a process of manufacturing the nitride semiconductor laser device of the sixth embodiment is described.

First, using the same process as that of the first embodiment, the n-type clad layer 2, the active layer 3, the p-type clad layer 4, and the p-type contact layer 5 are developed in sequence on the n-type GaN substrate 1. Thereafter, as shown in FIG. 54, using the electron beam evaporation technique, the p-side ohmic electrode 506 is formed on the p-type contact layer 5.

In addition, in the sixth embodiment, when forming the p-side ohmic electrode 506, the Pt layer 506a (refer to FIG. 55) having a thickness of about 1 nm and the Pd layer 506b having a thickness of about 20 nm are formed in sequence. Then, as shown in FIG. 54, the current block layer 7 is formed in the same way as that of the first embodiment.

Subsequently, using the electron beam evaporation technique, on a predetermined region of an upper surface of the p-side ohmic electrode 506 and of the current block layer 7, a Ti layer (not shown) having a thickness of about 100 nm, a Pd layer (not shown) having a thickness of about 200 nm, and an Au layer (not shown) having a thickness of about 300 nm are deposited in sequence from the side of the p-side ohmic electrode 506. Thereby, the pad electrode 508 is formed. Then, the n-type GaN substrate 1 is formed to have a thickness of about 100 nm by means of polishing and etching. Thereafter, using the same process as that of the first embodiment, the n-side ohmic electrode 509 is formed on a predetermined region of a lower surface of the n-type GaN substrate 1. Incidentally, the n-side ohmic electrode 509 is formed of the Si layer 509a, the Al layer 509b having a thickness of about 6 nm, and the Pd layer 509c having a thickness of about 30 nm. In addition, the pad electrode 10 having the same configuration and thickness as those of the first embodiment is formed on a lower surface of the n-side ohmic electrode 509.

### Seventh Embodiment

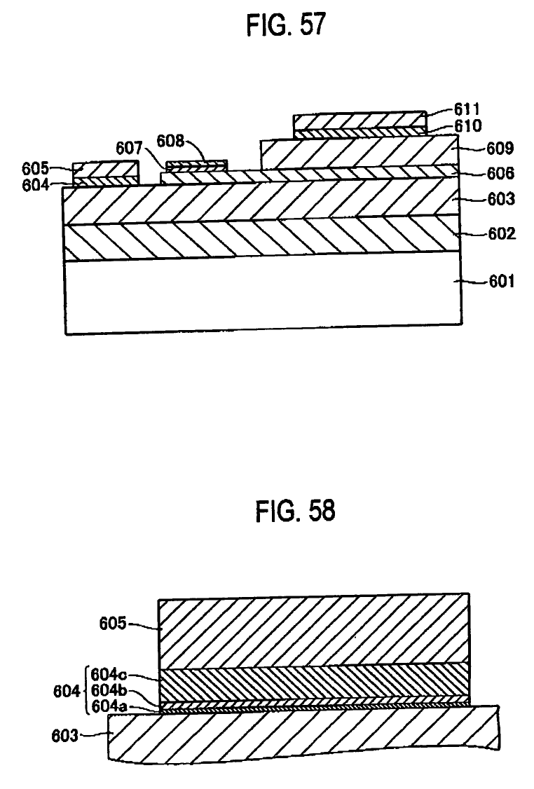

FIG. 57 is a sectional view showing a structure of a bipolar transistor (a nitride semiconductor device) of a seventh embodiment. FIGS. 58 to 60 are views for describing in detail the structure of the bipolar transistor of the seventh embodiment shown in FIG. 57. Referring to FIGS. 57 to 60, a description will be given for a case where, unlike the first to sixth embodiments, the nitride semiconductor device of the present invention is applied to a bipolar transistor.

In the bipolar transistor of the seventh embodiment, as shown in FIG. 57, an undoped n-type GaN layer 602 having a thickness of about 500 nm and an n-type collector layer 603 configured of GaN having a thickness of about 300 nm, are formed on a sapphire substrate 601. Incidentally, the n-type collector layer 603 is one example of the “n-type nitride semiconductor device” of the present invention. A collector ohmic electrode 604 is formed on a predetermined region of the n-type collector layer 603. Incidentally, the collector ohmic electrode 604 is one example of the “ohmic electrode” of the present invention. As shown in FIG. 58, this collector ohmic electrode 604 is configured of a Si (silicon) layer 604a, which is configured of amorphous silicon having a thickness of about 1 nm which contacts with a surface of the collector layer 603; an Al layer 604b having a thickness of about 6 nm; and a Pd layer 604c having a thickness of about 30 nm. The Si layer 604a, the Al layer 604b, and the Pd layer 604c are disposed in the above sequence from the side of the collector layer 603. Incidentally, the Al layer 604b and the Pd layer 604c are examples of the “first metal layer” of the present invention. Furthermore, a pad electrode 605 including an Al layer having a thickness of about 300 nm is formed on the collector ohmic electrode 604. Incidentally, the pad electrode 605 is one example of the “second metal layer” of the present invention

Moreover, in the seventh embodiment, a p-type base layer 606 having a thickness of about 200 nm configured of InₓGa₁₋ₓN (x=0.02) doped with Mg, is formed on a region of the collector layer 603 separated by a predetermined distance from the collector ohmic electrode 604 and the pad electrode 605. Incidentally, the p-type base layer 606 is one example of the “p-type nitride semiconductor device” of the present invention. Furthermore, a base ohmic electrode 607 is formed on a predetermined region of the p-type base layer is 606. Incidentally, the base ohmic electrode 607 is one example of the “ohmic electrode” of the present invention. As shown in FIG. 59, this base ohmic electrode 607 includes a Si layer 607a, which is configured of amorphous silicon having a thickness of about 1 nm which contacts with a surface of the base layer 606, and a Pd layer 607b having a thickness of about 20 nm. The Si layer 607a and the Pd layer 607b are disposed in the above sequence from the side of the base layer 606. Incidentally, the Pd layer 607b is one example of the “first metal layer” of the present invention. Furthermore, a pad electrode 608 formed of an Au layer having a thickness of about 10 is formed on the base ohmic electrode 607. Incidentally, the pad electrode 608 is one example of the “second metal layer” of the present invention.

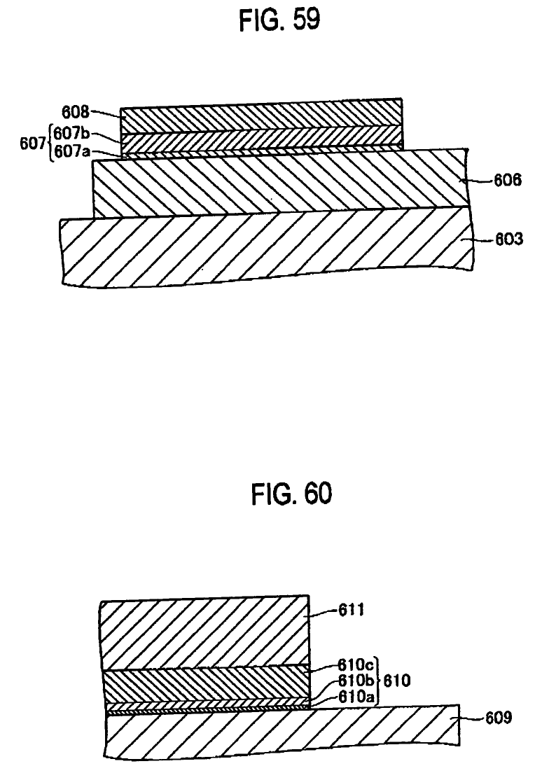

In addition, in the seventh embodiment, an n-type emitter layer 609 configured of GaN having a thickness of about 300 nm, is formed on a region of the base layer 606 separated by a predetermined distance from the base ohmic electrode 607 and from the pad electrode 608. Incidentally, the n-type emitter layer 609 is one example of the “n-type nitride semiconductor device” of the present invention. An emitter ohmic electrode 610 is formed on a predetermined region of the n-type emitter layer 609. Incidentally, the emitter ohmic electrode 610 is one example of the “ohmic electrode” of the present invention. As shown in FIG. 60, this emitter ohmic electrode 610 includes a Si layer 610a configured of amorphous silicon having a thickness of about 1 nm which contacts with a surface of the emitter layer 609, an Au layer 610b having a thickness of about 6 nm, and a Pd layer 610c having a thickness of about 30 nm. The Si layer 610a, the Au layer 610b, and the Pd layer 610c are disposed in the above sequence from the side of the emitter layer 609. Incidentally, the Al layer 610b and the Pd layer 610c are examples of the “first metal layer” of the present invention. Furthermore, a pad electrode 611, which is formed of an Au layer having a thickness of about 300 nm, is formed on the emitter ohmic electrode 610. Incidentally, the pad electrode 611 is one example of the “second metal layer” of the present invention.

Next, a description will be given for results of measurement of current amplification factor (rate of increase of collector current to base current) in the case of the bipolar transistor of the nitride semiconductor device of the seventh embodiment. Incidentally, as a comparative example, current amplification factors are measured also for a bipolar transistor formed of a conventional nitride semiconductor device. In the conventional nitride semiconductor device, the collector ohmic electrode is provided with Al and Pd layers and not with a Si layer; the base ohmic electrode is provided with a Pd layer only and not with a Si layer; and the emitter ohmic electrode is provided with Al and Pd layers and not with a Si layer. In the bipolar transistor of the seventh embodiment, a current amplification factor after the wafer process is about 13, and a current amplification factor after the assembling process is also about 13. In contrast, in the bipolar transistor formed of the conventional nitride semiconductor device, a current amplification factor after the wafer process is about 13, which is the same as that of the aforementioned seventh embodiment, and a current amplification factor after the assembling process is decreased to about 10. A reason for the above results can be considered as follows. In the bipolar transistor formed of the conventional nitride semiconductor device, due to the heat of about 250° C. to 350° C., the ohmic characteristics among the collector, the base, and the emitter are deteriorated whereby voltage drop occurs on an interface between the collector ohmic electrode 604 and the collector layer 603, an interface between the base ohmic electrode 607 and the base layer 606, and on an interface between the emitter ohmic electrode 610 and the emitter layer 609. Prom the above results, it has been confirmed that, even when the bipolar transistor is used for a bipolar transistor, deterioration of the ohmic characteristics among the collector, the base, and the emitter can be suppressed, the deterioration being caused by the heat of about 250° C. to 350° C. applied during soldering in the assembling process.

As described above, in the seventh embodiment, the collector ohmic electrode 604 is configured of the Si (silicon) layer 604a having a thickness of about 1 nm which contacts with a surface of the collector layer 603, the Al layer 604b having a thickness of about 6 nm, and the Pd layer 604c having a thickness of about 30 nm; the base ohmic electrode 607 is configured of the Si layer 607a having a thickness of about 1 nm which contacts with a surface of the base layer 606, and the Pd layer 607b having a thickness of about 20 nm; and the emitter ohmic electrode 610 is configured of the Si layer 610a having a thickness of about 1 nm which contacts with a surface of the emitter layer 609, the Au layer 610b having a thickness of about 6 nm, and the Pd layer 610c having a thickness of about 30 nm. Accordingly, as in the case of the first embodiment, even when the heat of about 250° C. to about 350° C. is applied during soldering in the assembling of the collector ohmic electrode 604, the base ohmic electrode 607, and the emitter ohmic electrode 610 after the forming of the same, ohmic characteristics are not easily deteriorated due to the effects of the Si layers 604a, 607a, and 610a, in which the Si layers 604a, 607a, and 610a contact with the main surfaces of the contact layer 603, the base layer 606, and the emitter layer 609, respectively. Accordingly, deterioration of the ohmic characteristics between the collector ohmic electrode 604 and the collector layer 603, between the base ohmic electrode 607 and the base layer 606, and between the emitter ohmic electrode 610 and the emitter layer 609, can be suppressed.

Incidentally, other effects of the seventh embodiments are the same as those of the first embodiment

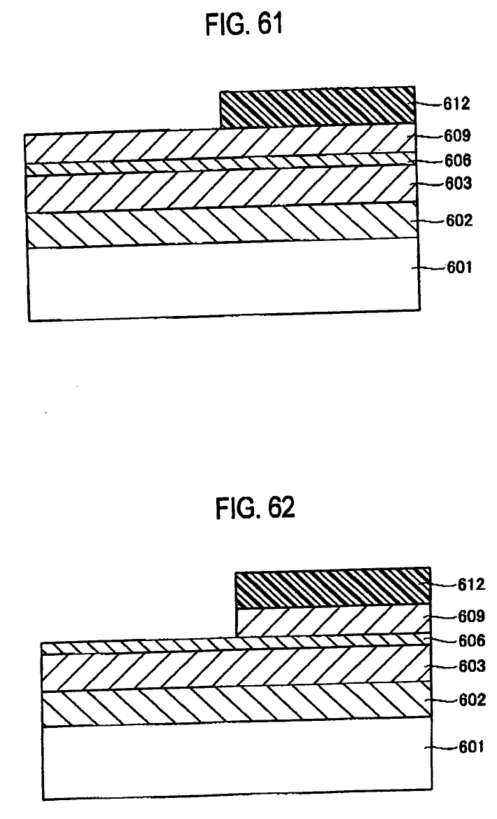

FIGS. 61 to 64 are sectional views for describing a process of manufacturing the bipolar transistor of the seventh embodiment shown in FIG. 57. Next, referring to FIGS. 57 to 64, the process of manufacturing the bipolar transistor of the seventh embodiment is described.

First, as shown in FIG. 61, using the MOCVD technique, the undoped n-type GaN layer 602, the n-type collector layer 603, the p-type base layer 606, and the n-type emitter layer 609 are developed in sequence on the sapphire substrate 601. The n-type GaN layer 602 has a thickness of about 500 nm; the n-type collector layer 603 is configured of GaN, and has a thickness of about 300; the p-type base layer 606 has a thickness of about 200 nm, and is configured of InₓGa₁₋ₓN (x=0.02) doped with Mg; and the n-type emitter layer 609 is configured of GaN, and has a thickness of about 300 nm. Then, using the photolithographic technique, a resistor 612 is formed on the emitter layer 609.

Subsequently, with the resistor 612 disposed as a mask, a predetermined region of the emitter layer 609 is removed using the RIE technique.

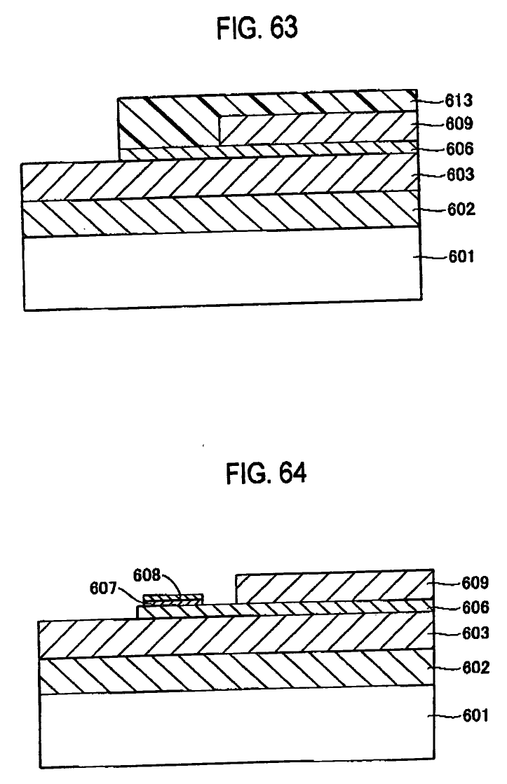

Then, as shown in FIG. 63, using the photolithographic technique, a resistor 613 is formed on each of the predetermined regions of the base layer 606 and the emitter layer 609. Thereafter, with the resistor 613 disposed as a mask, a predetermined region of the base layer 606 is removed using the RIE technique.

Then, as shown in FIG. 64, using the electron beam evaporation technique, the base ohmic electrode 607, and the pad electrode 608 configured of an Au layer having a thickness of about 10 nm, are formed on the base layer 606. When forming the base ohmic electrode 607, the Si layer 607a (refer to FIG. 59) having a thickness of about 1 nm and the Pd layer 607b having a thickness of about 20 nm are formed in sequence. At this time, since the Si layer 607a is formed using the electron beam evaporation technique, the Si layer 607a is formed as amorphous silicon.

Thereafter, as shown in FIG. 57, using the electron beam evaporation technique, the collector ohmic electrode 604 and the pad electrode 605 configured of the Au layer having a thickness of about 300 nm, are formed on the n-type collector layer 603; and the emitter ohmic electrode 610 and the pad electrode 611 configured of the Au layer having a thickness of about 300 nm, are formed on the emitter layer 609. Note that, when forming the collector ohmic electrode 604, the Si layer 604a having a thickness of about 1 nm, the Al layer 604b having a thickness of about 6 nm, and the Pd layer 604c having a thickness of about 30 nm, are formed in sequence. In addition, when forming the emitter ohmic electrode 610, using the same process as that for the aforementioned collector ohmic electrode 604, the Si layer 610a having a thickness of about 1 nm, the Al layer 610b having a thickness of about 6 nm, and the Pd layer 610c having a thickness of about 30 nm, are formed in sequence. At this time, since the Si layers 604a and 610a are formed using the electron beam evaporation technique, the Si layers 604a and 610a are formed as amorphous silicon.

### Eighth Embodiment

Hereinafter, an eighth embodiment of the present invention is described. Note that nitride semiconductor device of the eighth embodiment has the same configuration as that of the nitride semiconductor device of the aforementioned third embodiment. For this reason, differences between the third and eighth embodiments are mainly described below.

More specifically, in the aforementioned third embodiment, the n-side ohmic electrode 209 includes the Si layer 209a, the Al layer 209b, and the Pd layer 209c, which are stacked in the above sequence from the n-type clad layer 202. On the other hand, in the eighth embodiment, an n-type ohmic electrode includes a Si layer, a Pd layer (or a Pt layer), and an Al layer which are stacked in the above sequence from an n-type clad layer (an n-type nitride semiconductor device).

That is, in the eighth embodiment, the n-type ohmic electrode includes the Pd layer (or a Pt layer) located between the Si layer and the Al layer (a first metal layer).

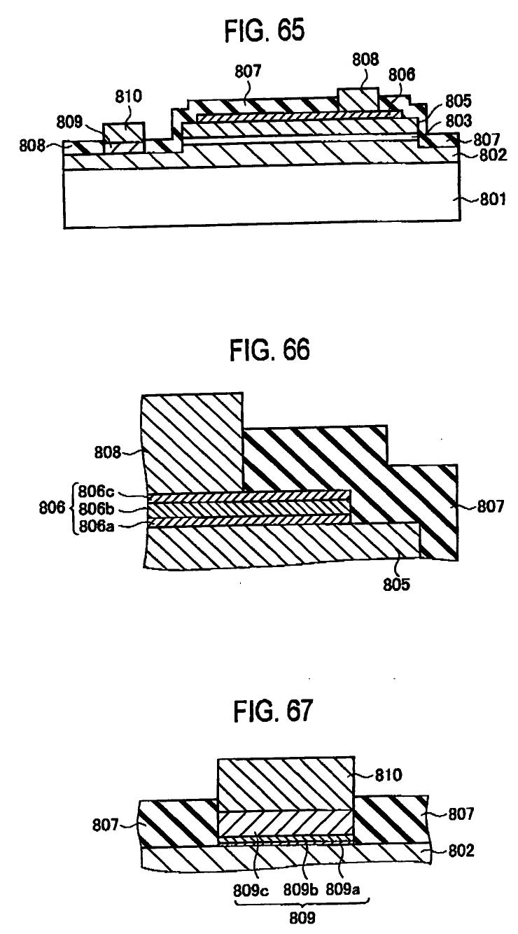

Hereinafter, a configuration of the nitride semiconductor device of the eighth embodiment is described with reference to drawings. FIG. 65 is a view showing the configuration of the nitride semiconductor device of the eighth embodiment.

As shown in FIG. 65, the nitride semiconductor device includes a sapphire substrate 801, an n-type clad layer 802, an active layer 803, a p-type contact layer 805, a p-side ohmic electrode 806, a surface protective Elm 807, a pad electrode 808, an n-side ohmic electrode 809, and a pad electrode 810.

The n-type clad layer 802 is configured of AlₓGa₁₋ₓN (x=0.07), and has a thickness of about 400 nm. The active layer 803 includes well layers configured of InₓGa₁₋ₓN (x=0.15) and barrier layers configured of InₓGa₁₋ₓN (x=0.02), and the well layers and the barrier layers are alternately stacked. In addition, each of the well layers has a thickness of about 3 nm, and each of the barrier layers has a thickness of about 20 nm.

The p-type clad layer 805 is configured of AlₓGa₁₋ₓN (x=0.07), and has a thickness of about 400 nm. In addition, p-type contact layer 805 is doped with Mg as a dopant material. Furthermore, a p-type contact layer (not shown) doped with Mg as a dopant material is stacked on the p-type clad layer 805.

As shown in FIG. 66, the p-side ohmic electrode 806 includes a Si layer 806a, a Pd layer 806b, and an Au layer 806c. The Si layer 806a, the Pd layer 806b, and the Au layer 806c are stacked in this sequence from the side of the p-type contact layer 805. The Si layer 806a has a thickness of about 1 nm, the Pd layer 806b has a thickness of about 30 nm; and the Au layer 806c has a thickness of about 300 nm.

Incidentally, as described above, it is preferable that the Si layer 806a be configured of amorphous silicon. Furthermore, the p-side ohmic electrode 806 may include a Pt layer in place of the Pd layer 806b.

The surface protective layer 807 is configured of SiO₂, and is disposed to cover the n-type clad layer 802 and the p-side ohmic electrode 806.

The pad electrode 808 is configured of, for example, a Si, a Ti, and an Au; and these Si, Ti, and Au are stacked in this sequence from the side of the p-side ohmic electrode 806. In addition, the Si has a thickness of about 3 nm; the Ti has a thickness of about 200 nm; and the Au has a thickness of about 300 nm.

The n-side ohmic electrode 809 includes, as shown in FIG. 67, the Si layer 809a, the Pd layer 809b, and the Al layer 809c. The Si layer 809a, the Pd layer 809b, and the Al layer 809c are stacked in this sequence from the side of the n-type clad layer 802. In addition, the Si layer 809a has a thickness of about 3 nm; the Pd layer 809b has a thickness of about 2 nm; and the Al layer 809c has a thickness of about 6 nm.

Incidentally, as described above, it is preferable that the Si layer 809a be configured of amorphous silicon. In addition, the n-side ohmic electrode 809 may include a Pt layer in place of the Pd layer 809b.

The pad electrode 810 is configured of, for example, a Si, a Ti, and an Au; and these Si, Ti, and Au are staked in this sequence from the side of the n-side ohmic electrode 809. In addition, the Si has a thickness of about 3 nm; the Ti has a thickness of about 200 nm; and the Au has a thickness of about 300 nm.

Note that the description of a process of manufacturing the nitride semiconductor device of the eighth embodiment is omitted since the process thereof is the same as that of the aforementioned third embodiment.

### Ninth Embodiment

Hereinafter, a ninth embodiment of the present invention is described. Note that a nitride semiconductor device of the eighth embodiment has the same configuration as that of the nitride semiconductor device of the aforementioned second embodiment. For this reason, differences between the aforementioned second and ninth embodiments are mainly described below.

More specifically, in the aforementioned second embodiment, the n-side ohmic electrode 9 is configured of the Si layer 9a, the Al layer 9b, and the Pd layer 9e, which are stacked in the above sequence from the n-type GaN substrate 1. On the other hand, in the ninth embodiment, an n-type ohmic electrode includes a Si layer, a Pd layer (or a Pt layer), and an Al layer, which are stacked in the above sequence from an u-type clad layer (an n-type nitride semiconductor device).

That is, in the ninth embodiment, the n-type ohmic electrode includes the Pd layer (or a Pt layer) located between the Si layer and the Al layer (a first metal layer).

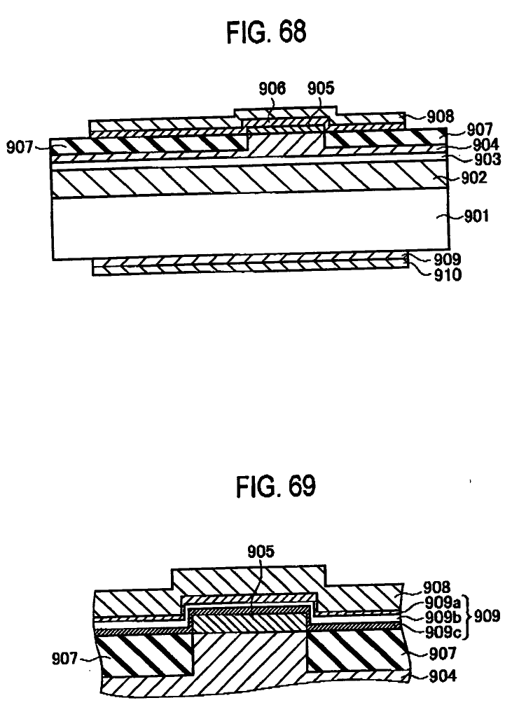

Hereinafter, a configuration of the nitride semiconductor device of the eighth embodiment is described with reference to drawings. FIG. 68 is a view showing the configuration of the nitride semiconductor device of the ninth embodiment.

As shown in FIG. 68, the nitride semiconductor device includes an n-type GaN substrate 901, an n-type clad layer 902, an active layer 903, a p-type clad layer 904, a p-type contact layer 905, a p-side ohmic electrode 906, a current block layer 907, a pad electrode 908, an n-side ohmic electrode 909, and a pad electrode 910.

The n-type clad layer 902 is configured of AlₓGa₁₋ₓN (x=0.07) and has a thickness of about 400 nm. The active layer 903 includes well layers configured of InₓGa₁₋ₓN (x=0.15) and barrier layers configured of InₓGa₁₋ₓN (x=0.02), and the well layers and the barrier layers are alternately stacked. In addition, each of the well layers has a thickness of about 3 nm, and each of the barrier layers has a thickness of about 20 nm.

The p-type clad layer 904 is configured of AlₓGa₁₋ₓN (x=0.07), and has a thickness of about 400 nm. Note that the p-type clad layer 904 is doped with Mg as a dopant material.

The p-type contact layer 905 is configured of InₓGa₁₋ₓN (x=0.02), and has a thickness of about 10 nm. Note that the p-type contact layer 906 is doped with Mg as a dopant material.

As shown in FIG. 69, the p-side ohmic electrode 906 includes a Si layer 906a, a Pd layer 906b, and an Au layer 906c. The Si layer 906a, the Pd layer 906b, and the Au layer 906c are stacked in this sequence from the side of the p-type contact layer 905. Moreover, the Si layer 906a has a thickness of about 1 nm; the Pd layer 906b has a thickness of about 30 nm; and the Au layer 906c has a thickness of about 300 nm.

Incidentally, as described above, it is preferable that the Si layer 906a be configured of amorphous silicon. Furthermore, the p-side ohmic electrode 906 may include a Pt layer in place of the Pd layer 906b.

The current block layer 907 is configured of SiO₂, and has a thickness of about 300 nm. Furthermore, the current block layer 907 is provided on the p-type clad layer 904.

The pad electrode 908 is configured of, for example, a Si, a Ti, and an Au; and these Si, Ti, and Au are stacked in this sequence from the side of the p-side ohmic electrode 906. In addition, the Si has a thickness of about 3 nm; the Ti has a thickness of about 200 nm; and the Au has a thickness of about 300 nm.

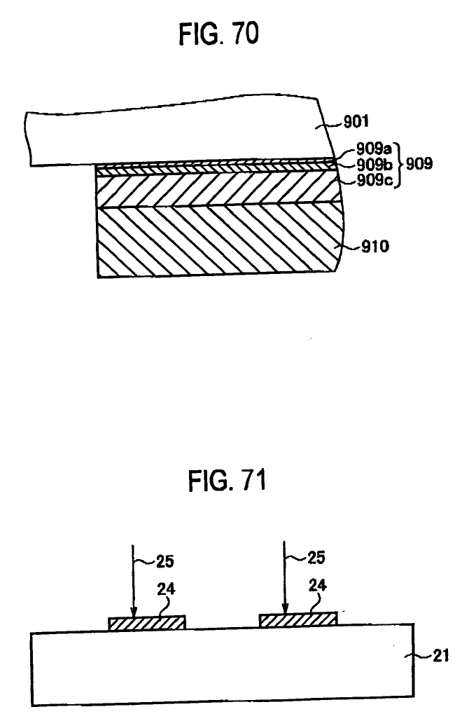

The n-side ohmic electrode 909 includes, as shown in FIG. 70, the Si layer 909a, the Pd layer 909b, and the Al layer 909c. The Si layer 909a, the Pd layer 909b, and the Al layer 909c are stacked in this sequence from the side of the n-type GaN substrate 901. In addition, the Si layer 909a has a thickness of about 3 nm; the Pd layer 909b has a thickness of about 2 nm; and the Al layer 909c has a thickness of about 6 nm.

Incidentally, as described above, it is preferable that the Si layer 909a be configured of amorphous silicon. In addition, the n-side ohmic electrode 909 may include a Pt layer in place of the Pd layer 909b.

The pad electrode 910 is configured of, for example, a Si, a Ti, and an Au; and these Si, Ti, and Au are stacked in this sequence from the side of the n-side ohmic electrode 909. In addition, the Si has a thickness of about 3 nm; the Ti has a thickness of about 200 nm; and the Au has a thickness of about 300 nm.

Incidentally, the description of a process of manufacturing the nitride semiconductor device of the ninth embodiment is omitted since the process thereof is the same as that of the aforementioned second embodiment.

Hereinafter, a description will be given for an experiment for validating effects of the n-side ohmic electrodes of the eighth and ninth embodiments.

First, a description is given for a sample for validating an effect of an n-side ohmic electrode, and for a method of validation. FIG. 71 is a view for describing the sample for validating an effect of an n-side ohmic electrode, and the method of validation.

As shown in FIG. 71, using the vacuum evaporation method, n-side ohmic electrodes 24 are formed in the state of being separated from one another by a predetermined distance, on an n-type GaN substrate 21.

Note that for samples of the ohmic electrodes 24, the following four kinds of samples are prepared. More specifically, samples, which are formed as samples of the n-side ohmic electrodes of the eighth and ninth embodiments of the present invention, are: a sample (hereinafter, referred to as a Si/Pd/Al (3/2/6 nm) sample), in which a Si layer (3 nm), a Pd layer (2 nm), and an Au layer (6 nm) are stacked in sequence from the side of the n-type GaN substrate 21; and a sample (hereinafter, referred to as a Si/Pt/Al (3/2/6 nm) sample), in which a Si layer (3 nm), a Pt layer (2 nm), and an Au layer (6 nm) are stacked in sequence from the side of the n-type GaN substrate 21. On the other hand, samples, which are formed as samples of a nitride semiconductor device for a comparative example are: a sample (hereinafter, referred to as an Al/Pd (6/10 nm) sample), in which an Al layer (6 nm) and a Pd layer (10 nm) are stacked in sequence from the side of the n-type GaN substrate 21; and a sample (hereinafter, referred to as an Al/Pt (6/10 nm) sample), in which an Al layer (6 nm) and a Pt layer (10 nm) are stacked in sequence from the side of the n-type GaN substrate 21.

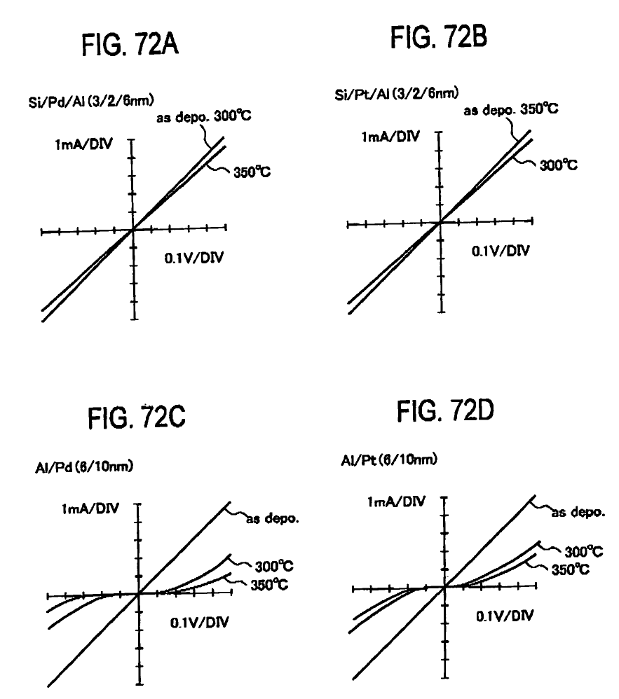

First, a description will be given for results of measurement of the current-voltage characteristics (I-V characteristics, which is measured with a measuring pointers 25 contacting with the n-side ohmic electrodes 24, FIGS. 72(a) to 72(d) are views showing current-voltage characteristics (I-V characteristics) of the respective samples of this experiment. Note that FIGS. 72(a) to 72(d) show current-voltage characteristics obtained right after the n-side ohmic electrode 24 is evaporated on the n-type GaN substrate 21, and those obtained after heat treatment is performed on the n-side ohmic electrode 24 in a nitrogen atmosphere.

As shown in FIGS. 72(a) and 72(b), in the cases of the Si/Pd/Al (3/2/6 nm) sample and the Si/Pt/Al (3/2/6 nm) sample, I-V characteristics are found to be hardly deteriorated even when a heat of 350° C. is applied, the heat thereof being the same as that of heat treatment (a die bond) performed in the assembling process.

In contrast, as shown in FIGS. 72(c) and 72(d), in the cases of the Al/Pd (6/10 nm) sample and the Al/Pt (6/10 nm) sample, it has been confirmed that, when applying a heat of 300° C., I-V characteristics is steeply deteriorated.

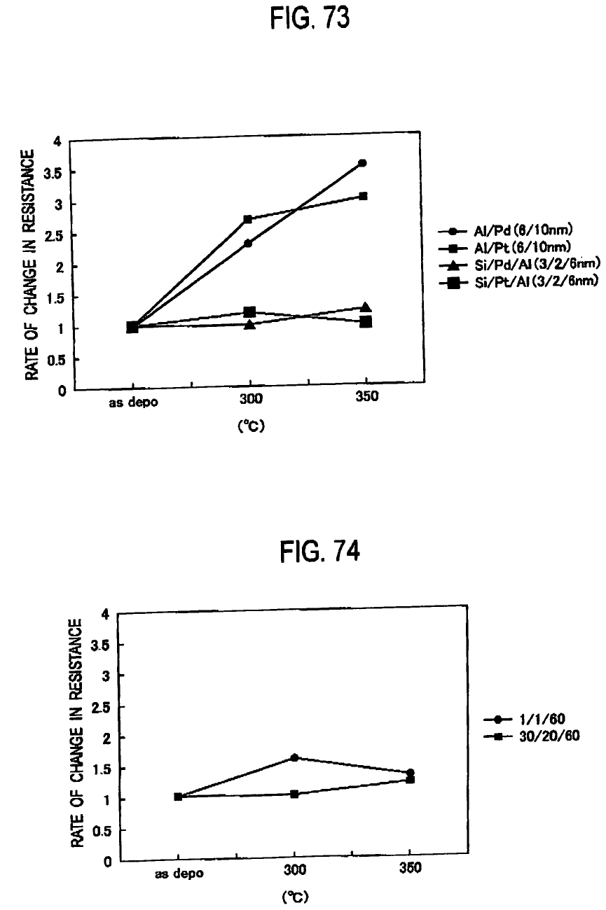

Next, normalization is carried out using resistance in the following state as a standard. The state (as depo. state) is one where the n-side ohmic electrode 24 is not subjected to heat treatment after the n-side ohmic electrode 24 is evaporated on the n-type GaN substrate 21. Then, rates of change in resistance, which change when performing heat treatment on the n-side ohmic electrode 24, are measured. FIG. 73 is a view showing rates of change in resistance of the respective samples of this experiment.

As shown in FIG. 73, in the cases of the Si/Pd/Al (3/2/6 nm) sample and the Si/Pt/Al (3/2/6 nm) sample, it has been confirmed that, even when heat treatment is performed on the respective samples, resistance hardly changes. In contrast, in the cases of the Al/Pd (6/10 nm) sample and the Al/Pt (6/10 nm) sample, it has been confirmed that, when the heat of 300° C. is applied, resistance is steeply deteriorated.

As is clear from the results of the experiment in FIGS. 72 and 73, in the case of the n-side ohmic electrode, in which the Si layer, Pd layer (or a Pt layer), and the Al layer are stacked in this sequence, i.e., the n-side ohmic electrode, which is provided with the Pd layer (or a Pt layer) disposed between the Si layer and the Al layer (a first metal layer), it has been confirmed that the reduction of ohmic characteristics due to heat treatment performed in the assembling process can be suppressed.

Lastly, two kinds of samples, in which the Si layer, the Pd layer (or a Pt layer), and the Al layer each have different thicknesses, are prepared. Then, rates of change in resistance of the respective samples are measured. FIG. 74 is a view showing rates of change in resistance of the respective samples of this experiment.

Note that, in this experiment, samples, which are made as samples of the n-side ohmic electrode 23 are: a sample (hereinafter, referred to as a 1/1/60 sample), in which a Si layer, a Pd layer (or a Pt layer), and an Au layer have thicknesses of 1 nm, 1 nm, and 60 nm, respectively; and a sample (hereinafter, referred to as a 30/20/60 sample), in which a Si layer, a Pd layer (or a Pt layer), and an Al layer have thicknesses of 30 nm, 20 nm, and 60 nm, respectively.

As shown in FIG. 74, it has been confirmed that, when thicknesses of the Si layer and the Pd layer (or a Pt layer) are changed, rates of change in resistance change. That is, the rates of change in resistance have characteristics, which depend on the thicknesses of the Si layer and the Pd layer (or a Pt layer).

### Other Embodiments

It should be noted that the disclosed embodiments above are to be considered in all respects as illustrative and not restrictive. The scope of the invention is indicated by the appended claims rather than the foregoing description, and all changes, which come with the meaning and range of equivalency of the claims, are therefore intended to be embraced therein.

For example, in the first to seventh embodiments, although descriptions are given for the examples where the nitride semiconductor device of the present invention, which is provided with an ohmic electrode being formed on nitride semiconductor layers, is applied to the nitride semiconductor laser device, the nitride semiconductor light-emitting diode device, and the bipolar transistor. However, the present invention is not limited to the above embodiments; and the nitride semiconductor device of the present invention, which is provided with an ohmic electrode formed on nitride semiconductor layers, may be applied to a nitride semiconductor device other than the nitride semiconductor laser device, the nitride semiconductor light-emitting diode device, and the bipolar transistor.

Furthermore, in the fifth embodiment, descriptions are given for the examples where a Pt (Pd) layer, which contacts with a p-type contact layer, is a formed in an insular shape on the p-type contact layer; and where a Si layer is formed on a portion of the p-type contact layer, on which the Pt (Pd) layer is not formed, so that the Si layer contacts with the portions thereof. However, the present invention is not limited to the above embodiments; and Pt (Pd) layers may be farmed in layers on the p-type contact layer, and the Si to layer may be formed on the Pt (Pd) layers in layers.

What is claimed is:

1. A nitride semiconductor device, comprising:
a nitride semiconductor layer having a main surface; and
an ohmic electrode formed on the main surface of the nitride semiconductor layer, wherein,
the ohmic electrode includes a silicon layer formed to contact with the main surface of the nitride semiconductor layer, and a first metal layer formed on the silicon layer.

2. The nitride semiconductor device according to claim 1, wherein,
the first metal layer includes a metal forming an ohmic contact with the nitride semiconductor layer.

3. The nitride semiconductor device according to claim 1, wherein,
the ohmic electrode is formed on the nitride semiconductor layer of p-type, and
the first metal layer contains at least one of Pd and Pt

4. The nitride semiconductor device according to claim 1, wherein,
the ohmic electrode is formed on the nitride semiconductor layer of n-type, and
the ohmic electrode further includes an Al layer disposed between the silicon layer and the first metal layer.

5. The nitride semiconductor device according to claim 1, wherein,
the ohmic electrode is formed on the nitride semiconductor layer of n-type, and
the ohmic electrode further includes at least one of a Pd layer and a Pt layer between the silicon layer and the first metal layer.

6. The nitride semiconductor device according to claim 1, wherein,
the silicon layer is configured of amorphous silicon.

7. The nitride semiconductor device according to claim 1, further comprising,
a second metal layer formed on the ohmic electrode.

8. The nitride semiconductor device according to claim 1, wherein,
the silicon layer has a thickness equal to or more than 0.5 nm and equal to or less than 30 nm.

9. A nitride semiconductor device, comprising:
a p-type nitride semiconductor layer; and
an ohmic electrode formed on the p-type nitride semiconductor layer, wherein,
the ohmic electrode includes a silicon layer formed on the p-type nitride semiconductor layer, and a first metal layer formed on tho silicon layer.

10. The nitride semiconductor device according to claim 9, wherein,
an ohmic metal layer is provided between the p-type nitride semiconductor layer and the silicon layer, the ohmic metal layer forms an ohmic contact with the p -type nitride semiconductor layer.

11. A nitride semiconductor device, comprising:
an n-type nitride semiconductor layer; and
an ohmic electrode formed on the n-type nitride semiconductor layer, wherein,
the ohmic electrode includes a silicon layer formed on the n-type nitride semiconductor layer, and a first metal layer firmed on the silicon layer,
the first metal layer includes a material to form an ohmic contact with the n-type nitride semiconductor layer, and
the ohmic electrode includes at least one of a Pd layer and a Pt layer between the silicon layer and the first metal layer.

12. The nitride semiconductor device according to claim 11, wherein, the silicon layer is configured of amorphous silicon.
